(19) United States
(12) Patent Application Publication
(10) Pub. No.: US 2025/0189739 A1
(43) Pub. Date: Jun. 12, 2025

(54) OPTICAL CIRCUITS AND SIGNAL PROCESSING

(71) Applicant: University of Southern California, Los Angeles, CA (US)

(72) Inventors: Hossein Hashemi, Los Angeles, CA (US); Samer Idres, Los Angeles, CA (US)

(21) Appl. No.: 18/972,499

(22) Filed: Dec. 6, 2024

Related U.S. Application Data
(60) Provisional application No. 63/607,984, filed on Dec. 8, 2023.

(51) Int. Cl. G02B 6/43; G02F 1/225; H03K 19/14; H03K 19/21

(52) U.S. Cl. CPC G02B 6/43; G02F 1/225; H03K 19/14; H03K 19/21

(57) ABSTRACT

A universal optical digital logic circuit is disclosed. The universal optical digital logic circuit includes an optical waveguide configured to receive a continuous wave optical signal and emit an output signal, an optical combiner configured to receive first and second optical signals and combine the first and second optical signals to produce a combined optical signal, a photodetector configured to receive the combined optical signal and convert the output optical signal into an electrical voltage signal, and a resonator coupled to the optical waveguide and configured to receive the continuous wave optical signal and/or the electrical voltage signal. The optical waveguide is configured to emit the output signal based on the electrical voltage signal applied on the resonator.

### CROSS-REFERENCE TO RELATED PATENT APPLICATIONS

This application claims priority to and the benefit of U.S. Provisional Application No. 63/607,984, filed Dec. 8, 2023, entitled “Optical Digital Circuits and Digital Signal Processing,” which is incorporated herein by reference in its entirety for all purposes.

### STATEMENT REGARDING FEDERALLY SPONSORED RESEARCH OR DEVELOPMENT

This invention was made with Government support under Contract No. HR001120C0088 awarded by the Defense Advanced Research Projects Agency (DARPA). The Government has certain rights in this invention.

### BACKGROUND

The following description is provided to assist the understanding of the reader. None of the information provided or references cited is admitted to be prior art.

Digital circuits process electrical signals with discrete logic levels, typically “0” and “1,” but their power consumption increases with speed. In contrast, optical processing, which manipulates information directly in the optical domain, offers the potential for reduced power consumption and higher speed by avoiding the need for electrical conversions. Advancements like optical digital signal processors aim to enable efficient, high-speed information processing by leveraging the inherent advantages of optical systems, such as low latency and high bandwidth.

### SUMMARY OF THE INVENTION

Certain embodiments of the present disclosure relate to optical circuits (e.g., optical digital circuits, optical logic circuit, etc.). More specifically, certain embodiments of the disclosure relate to digital logic gates and digital circuits with optical inputs and optical outputs. Optical digital circuits and optical digital signal processing methods are introduced.

An aspect of the disclosure is directed to an optical circuit. The optical circuit includes an optical waveguide configured to receive a continuous wave optical signal and emit an output signal, an optical combiner configured to receive first and second optical signals and combine the first and second optical signals to produce a combined optical signal, a photodetector configured to receive the combined optical signal and convert the output optical signal into an electrical voltage signal, and a resonator coupled to the optical waveguide and configured to receive the continuous wave optical signal and/or the electrical voltage signal. The optical waveguide is configured to emit the output signal based on the electrical voltage signal applied on the resonator.

In some embodiments, the first and second optical signals have substantially the same wavelength and/or substantially the same phase. In some embodiments, (i) the first and second optical signals have a first optical power corresponding to a logic-high state, (ii) the first and second optical signals have a second optical power corresponding to a logic-low state, or (iii) the first optical signal has the first optical power, and the second optical signal has the second optical power.

In some embodiments, the resonator is a tunable microring resonator. In some embodiments, the output signal is dependent on a location of a resonant wavelength relative to a wavelength of the continuous wave optical signal.

Another aspect of the disclosure is directed to an optical logic circuit. The optical logic circuit includes an optical waveguide having a continuous wave optical signal coupled to an input of the optical waveguide, a first optical signal input waveguide having a first optical input signal, a second optical input signal waveguide having a second optical input signal, a combiner coupled to the first and second optical input signal waveguides to receive the first and second optical input signals and combine the first and second optical input signals into a combined input signal, an optical resonator coupled to the optical waveguide and configured to receive the combined input signal. The optical resonator is configured to change a resonant wavelength of the optical resonator based on an amplitude of the combined input signal. The optical waveguide is configured to output an output signal at an output of the optical waveguide, the output signal having an amplitude varying based on the resonant wavelength of the optical resonator.

In some embodiments, the optical resonator includes a microring resonator having a semiconductor junction biased by an electrical voltage corresponding to the amplitude of the combined input signal. In some embodiments, the combiner includes a first photodiode coupled to the first optical signal input waveguide and a second photodiode coupled to the second optical signal input waveguide. The combiner is configured to provide a first electrical signal and a second electrical signal based on the first optical input signal and the second optical input signal, respectively. The combined input signal includes the first electrical signal and the second electrical signal. In some embodiments, the optical circuit includes a power source coupled to the first photodiode and the second photodiode, the power source configured to provide a modulating voltage. The optical resonator is configured to receive the first electrical signal, the second electrical signal, and the modulating voltage. In some embodiments, the combiner includes a plurality of stacked photodiodes configured to receive the first optical input signal and the second optical input signal, and convert into one or more electrical signals. In some embodiments, the combiner includes a plurality of first stacked photodiodes configured to receive the first optical input signal and convert into one or more first electrical signals, and a plurality of second stacked photodiodes configured to receive the second optical input signal and convert into one or more second electrical signals.

Another aspect of the disclosure is directed to a universal optical logic circuit. The universal optical logic circuit includes a microring resonator including a plurality of inputs, a plurality of optical signal input waveguides coupled to the plurality of inputs of the microring resonator and configured to provide (i) a first logic input optical signal and (ii) a second logic input optical signal, and an optical waveguide coupled to the microring resonator and including an input configured to receive a continuous wave optical signal having a first input amplitude and an output configured to emit an output signal. The output is configured to emit the output signal having a logic state determined based on a first logical operation of the microring resonator on the first logic input optical signal and the second logic input optical signal.

In some embodiments, the output optical signal includes the CW optical signal having a first output amplitude. In some embodiments, the first output amplitude depends on the logic state. In some embodiments, the universal optical logic circuit includes a temperature controller configured to increase or decrease a temperature of the microring resonator to maintain the microring resonator at an approximately constant temperature. In some embodiments, the output optical signal has three states associated with a logic-high amplitude, a logic-low amplitude, and a logic-intermediate amplitude of the CW optical signal, respectively. Each of the logic-high amplitude, the logic-low amplitude, and the logic-intermediate amplitude is less than or equal to the first input amplitude. In some embodiments, the output optical signal has two states associated with a logic-high amplitude and a logic-low amplitude of the CW optical signal, respectively. Each of the logic-high amplitude and the logic-low amplitude is less than or equal to the first input amplitude. In some embodiments, the universal optical logic circuit is connected to another universal optical logic gate or circuit configured to perform at least one of (i) a logic operation to provide a one-bit digital full adder and (ii) an operation to provide a pattern detector. In some embodiments, the first logical operation includes at least one of a NAND operation, an OR operation, and an XNOR operation. In some embodiments, a resonant wavelength of the microring resonator is tuned by at least a first optical power of the first logic input optical signal and a second optical power of the second logic input optical signal. In some embodiments, universal optical logic circuit includes a coupler to extract a fraction of optical power from the first logical input optical signal and the second logical input optical signal, and a photodetector connected to the coupler to generate an electrical voltage having a magnitude proportional to the fraction of the optical power. The microring resonator includes a semiconductor junction having the electrical voltage applied across the semiconductor junction to bias the semiconductor junction. In some embodiments, the semiconductor junction is a P-N junction or a PIN junction.

Various aspects, embodiments, advantages, etc. of the present disclosure, as well as details of illustrated embodiments thereof, will be more understood from the following description and drawings.

### BRIEF DESCRIPTION OF THE DRAWINGS

The drawings are of illustrative embodiments. They do not illustrate all embodiments. Other embodiments can be used in addition or instead. Details that can be apparent or unnecessary can be omitted to save space or for more effective illustration. Some embodiments can be practiced with additional components or steps and/or without all of the components or steps that are illustrated. When the same numeral appears in different drawings, it refers to the same or like components or steps.

FIG. 1 shows symbolic examples of logic gates and associated truth tables (logical relationships between inputs and output) with one or two inputs and one output.

FIG. 2 shows examples of waveguide-coupled microring resonators where the optical signal entering the structure, referred to as the input optical signal, and the optical signal leaving the structure, referred to as the output optical signal, are designated.

FIG. 3 shows the conceptual response of such a waveguide-coupled microring resonator.

FIG. 4A shows conceptual geometry and responses of a waveguide-coupled tunable microring resonator with different voltages, V_{mod}, applied across the PN or PIN structure.

FIG. 4B shows example conceptual geometry and responses of a waveguide-coupled tunable microring resonator, in accordance with some embodiments.

FIG. 5 shows a schematic diagram of an example optical circuit, in accordance with various embodiments.

FIG. 6 shows a schematic diagram of an example optical circuit and an example waveform, in accordance with various embodiments.

FIG. 7 shows a schematic diagram of an example optical circuit, an example truth table, and an example waveform, in accordance with various embodiments.

FIG. 8 shows a schematic diagram of an example optical circuit, an example truth table, and an example waveform, in accordance with various embodiments.

FIG. 9 shows a schematic diagram of an example optical circuit, an example truth table, and an example waveform, in accordance with various embodiments.

FIG. 10 shows a schematic diagram of an example optical circuit, an example truth table, and an example waveform, in accordance with various embodiments.

FIG. 11 shows a schematic diagram of an example optical circuit, an example truth table, and an example waveform, in accordance with various embodiments.

FIG. 12 shows a schematic diagram of an example optical circuit, an example truth table, and an example waveform, in accordance with various embodiments.

FIG. 13 shows a schematic diagram of an example optical circuit, an example truth table, and an example waveform, in accordance with various embodiments.

FIG. 14A shows a schematic diagram of an example optical circuit, in accordance with various embodiments.

FIG. 14B shows a schematic diagram of an example optical circuit, in accordance with various embodiments.

FIG. 15A shows an example embodiment of a 1-bit digital full adder, in accordance with various embodiments.

FIG. 15B shows an example embodiment of a pattern detector, in accordance with various embodiments.

FIG. 16 shows a schematic diagram of an example optical circuit, in accordance with various embodiments.

FIG. 17 shows a schematic diagram of an example optical circuit, in accordance with various embodiments.

FIG. 18 shows a schematic diagram of an example optical circuit, in accordance with various embodiments.

FIG. 19 shows a schematic diagram of an example optical circuit, in accordance with various embodiments.

FIG. 20 shows a schematic diagram of an example optical circuit, in accordance with various embodiments.

FIG. 21A shows a schematic diagram of an example logic gate showing the main building blocks with the optical inputs combined in the optical domain, in accordance with various embodiments.

FIG. 21B shows an example resonant wavelength shift of the micro-ring resonator as a function of combined power level input to the photovoltaic photodiode, in accordance with various embodiments.

FIG. 21C shows an example operational principle of the OR gate for different input combinations, in accordance with various embodiments.

FIG. 21D shows an example operational principle of the NOR gate for different input combinations, in accordance with various embodiments.

FIG. 22A shows a schematic diagram of an example logic gate showing the main building blocks with the optical inputs combine coherently in the optical domain with 180° phase shift, in accordance with various embodiments.

FIG. 22B shows an example resonant wavelength shift of the micro-ring resonator as a function of combined power level input to the photovoltaic photodiode, in accordance with various embodiments.

FIG. 22C shows an example operational principle of the XOR gate for different input combinations, in accordance with various embodiments.

FIG. 22D shows an example operational principle of the XNOR gate for different input combinations, in accordance with various embodiments.

FIG. 23A shows a schematic diagram of an example design showing the building blocks and the input-output ports, in accordance with various embodiments.

FIG. 23B shows a micrograph of an example fabricated logic gate with ring modulator length of 250 μm showing the main building devices and the area size, in accordance with various embodiments.

FIG. 24 shows an optical power to voltage characterization with the measured open-circuit output voltage versus input static logic optical power (PA or PB) for different input logic PAB configurations: 00, 01, 10, 11, in accordance with various embodiments.

FIG. 25A and FIG. 25B show an example optical-optical logic gate static measurements with the measured wavelength transmission of the optical logic gate for different input logic cases (with high logic optical power PH=0.1 mW) of two operands and one operand, respectively, in accordance with various embodiments.

FIG. 26A and FIG. 26B show an example optical-optical logic gate dynamic measurements for 10 Mbps OOK input modulated signal, where PRBS OOK signal is the input to the logic gate PA and PB (in Red), and the optical output of the logic gate (in Blue) showing the operation of OR and NOR in case of two operands and NOT and Buffer in case of one operand, respectively, in accordance with various embodiments.

FIG. 27A shows optical logic gate speed measurements with the measured transient response with input square wave 2 MHz logic input signal (PA) for different optical carrier high level power PH of both the monitor signal Pmonitor (monitor the input power Pm to the optical power to voltage converter) in green (top) and the logic gate output signal Pout in blue (bottom) for an example microring design with Lmod=250 μm, in accordance with various embodiments.

FIG. 27B shows measured rise time and fall time (10%-90%) of an example logic gate output for different logic input power PA (top), and the corresponding −3 dB bandwidth values (bottom) for different Lmod designs, in accordance with various embodiments.

FIG. 28A shows a measured optical logic gate transfer function (output transmission Pout/Psup versus the input logic power PA) for three example different ring modulator geometries, in accordance with various embodiments.

FIG. 28B shows a total optical power for an example optical logic gate versus the input logic power PA, in accordance with various embodiments.

FIG. 28C shows a schematic diagram of an example optical logic gate driving F similar optical logic gates, in accordance with various embodiments.

FIG. 28D shows the minimum total power consumption of an example optical logic gate versus different values of fanout (F), in accordance with various embodiments.

FIG. 29A shows a schematic diagram of an example logic gate showing the main building blocks with the optical inputs combine in the electrical domain, in accordance with various embodiments.

FIG. 29B shows an example resonant wavelength shift of the micro-ring resonator as a function of power level of each input operand, in accordance with various embodiments.

FIG. 29C shows an example operational principle of the OR gate for different input combinations, in accordance with various embodiments.

FIG. 29D shows an example operational principle of the XNOR gate for different input combinations, in accordance with various embodiments.

FIG. 29E shows an example operational principle of the NAND gate for different input combinations, in accordance with various embodiments.

FIG. 30 an example optical-input optical-output zero-biased logic gate with electrical logic operands combining, in accordance with various embodiments.

FIG. 31 an example optical power to voltage characterization for the electrical operand combining shown in FIG. 30, in accordance with various embodiments.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments can be utilized, and other changes can be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and make part of this disclosure.

Digital circuits are ubiquitous in computing systems. The inputs and outputs in all such digital circuits are electrical signals. The signals present in most digital circuits have two logic levels commonly referred to as “0” and “1.” For instance, an electrical signal whose voltage level is close to zero can be associated with digital logic “0” and an electrical signal whose voltage level is close to the voltage supply level can be associated with digital logic “1.” The power consumption of digital circuits increases with the operating speed.

Real-world electrical signals, such as the electrical signals received by a microphone, a temperature or a pressure sensor, a wireless receiver, etc. are often analog (e.g., their value is not limited to two logical levels). To process the information of real-world analog electrical signals, these analog electrical signals are converted to digital electrical signals using analog to digital converter (ADC) circuits. In contrast, to convert the digital electrical signals to analog electrical signals, digital to analog converter (DAC) circuits are used. In some cases, the information signal resides in optical frequencies. For instance, a digital camera measures the intensity and wavelengths of optical signals in the visible spectrum and converts this information to electrical signals for further processing. The optical to electrical (O/E) conversion adds to the power consumption and latency. Also, the information carried by electrical signals can be sent (or modulated) to optical frequencies. For instance, to facilitate energy-efficient high-speed communication, the information of electrical signals is often modulated to optical frequencies to be carried by optical fibers. Optical communications are the backbone of the Internet and play an increasing role in transferring data among computing units of a data center. In optical communications, the information processing is still in the electrical domain. Hence, electrical to optical (E/O) as well as O/E conversions are needed adding to the power consumption and latency.

Therefore, it is highly desirable to process the information that is carried by optical signals directly and without converting it to electrical signals. Furthermore, it is highly desirable to digitally process the information that is carried by optical signals. In other words, it is highly desirable to create an optical digital signal processor (O-DSP).

Illustrative embodiments are now described. Other embodiments can be used in addition or instead. Details that can be apparent to a person of ordinary skill in the art can have been omitted. Some embodiments can be practiced with additional components or steps and/or without all of the components or steps that are described.

### A. Optical Circuits and Signal Processing

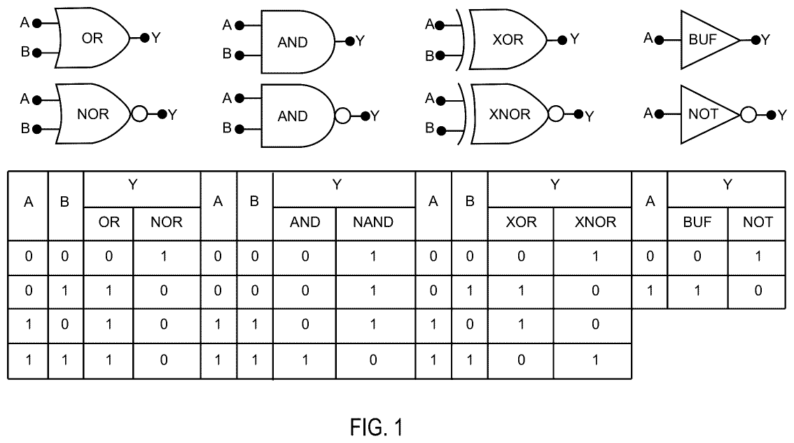

It is well known that electrical digital circuits rely on logic gates. FIG. 1 shows symbolic examples of logic gates and associated truth tables (logical relationships between inputs and output) with one or two inputs and one output. It should be noted that in electrical implementation of digital circuits, logic level “0” and logic level “1” correspond to two distinctly different voltage levels.

Digital circuits are realized using complementary metal oxide semiconductor (CMOS) logic gates. In CMOS logic gates, the output logic level (the voltage of the electrical output signal) is a nonlinear function of the electrical input voltage or voltages. An important property of CMOS logic gates is that the voltages that correspond to “0” and “1” logic levels remain intact. In other words, when the input voltages of a CMOS logic gate are either zero volts or VDD volts (the voltage of a supply, say 1 Volts), the output of the logic gate are also ideally either zero or VDD volts. This property allows for various logic gates to be connected in an appropriate configuration to construct a more complex digital circuit. The underlying reason for this property is the nonlinearity that is inherent in CMOS logic gates.

The lack of appropriate nonlinearity in the optical domain has been an impediment in realizing optical digital gates that are analogous to electrical digital gates. In photonic integrated circuits (PIC), the optical signal is often confined using optical waveguides. The optical signal travels through the optical waveguide. Ideally, the shape of the optical signal is not changed drastically as it travels through an optical waveguide. In a properly designed optical waveguide, the optical signal is only attenuated minimally.

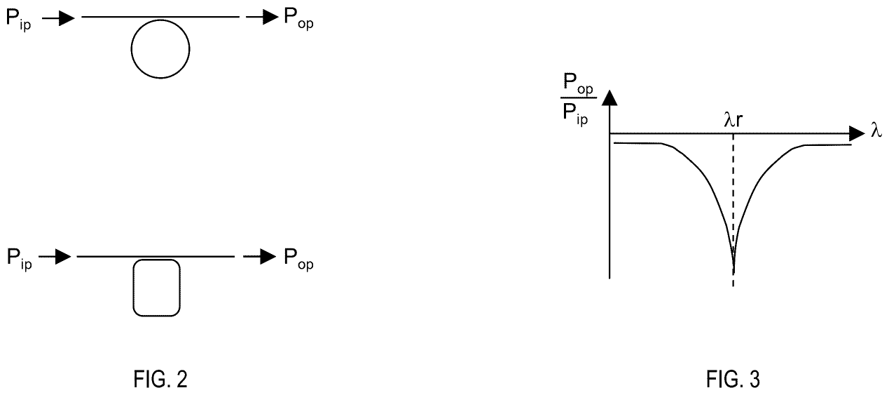

Another fundamental photonic component is an optical resonator. In a PIC, optical resonator can be realized by having a closed waveguide (e.g., resembling a circular ring or a racetrack) in the vicinity of another waveguide where the optical signal travels. The properties of the so-called waveguide-coupled microring resonator (MRR) depend on the geometries (e.g., size of the ring or racetrack, distance between the ring or racetrack and the other waveguide) and the optical properties of the waveguides among other things. FIG. 2 shows examples of waveguide-coupled microring resonators where the optical signal entering the structure, referred to as the input optical signal, and the optical signal leaving the structure, referred to as the output optical signal, are designated. Circular and racetrack geometries are shown as examples.

It is possible to design the waveguide-coupled microring resonator so that the input optical signal reaches the output at all wavelengths except for those that are at or the vicinity of a specific wavelength that is referred to as a resonant wavelength of the structure. It should be noted that there are several resonant wavelengths associated with such a resonator. FIG. 3 shows the conceptual response of such a waveguide-coupled microring resonator.

The resonant wavelength of a waveguide-coupled microring resonator can be modified by changing the effective refractive index of the waveguide that is used to construct the ring geometry. The effective refractive index can be modified using electro-optic, thermo-optic, or acousto-optic effects. As an example, the concentration of carriers (electrons and holes) in a waveguide affects the effective refractive index. The carrier concentration in a waveguide can be modified by using a positive-negative junction (PN) or a positive-intrinsic-negative (PIN) structure within the waveguide geometry where the voltage difference applied to the P and N terminals changes the carrier concentration where the optical field is.

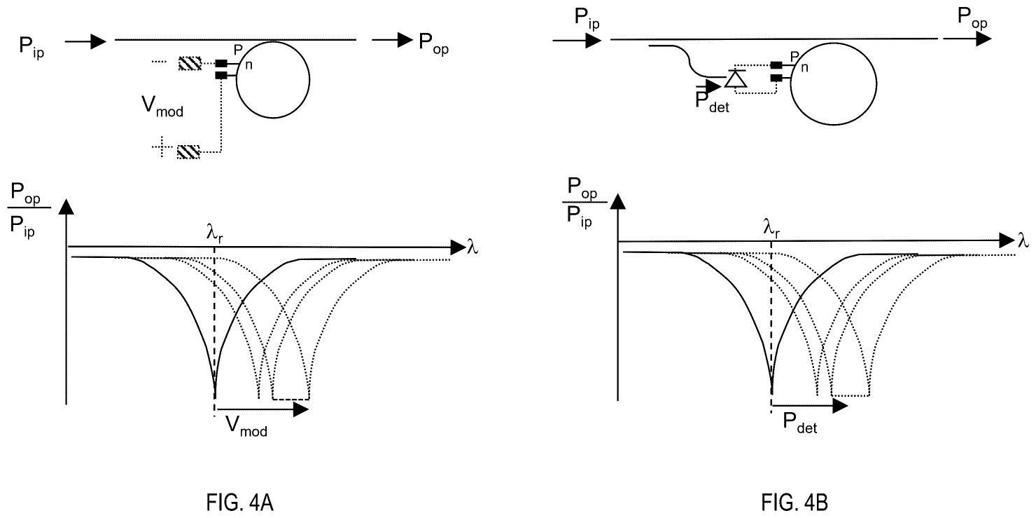

FIG. 4A shows conceptual geometry and responses of a waveguide-coupled tunable microring resonator with different voltages, V_{mod}, applied across the PN or PIN structure. It is evident that the resonant wavelength (null in the response) is a function of applied voltage across the PN or PIN. FIG. 4B shows example conceptual geometry and responses of a waveguide-coupled tunable microring resonator, in accordance with some embodiments. In this embodiment, the tunable waveguide-coupled microring resonator is tuned to create a nonlinear optical response by a fraction of the input light power. A coupler is used to extract a fraction of the input optical power. This fraction is then fed to a photodetector to create an electrical voltage whose value is proportional to the input optical power. The photodetector electrical voltage is then used to control the voltage of the PN or PIN in the tunable microring resonator. Therefore, the resonant wavelength of the waveguide-coupled tunable microring resonator changes as a function of input optical power. Consequently, at a given optical wavelength, the input-output response can be a function of input optical power. While conceptually shown in FIG. 4B, the nonlinear input-output response of this structure is discussed in greater detail below.

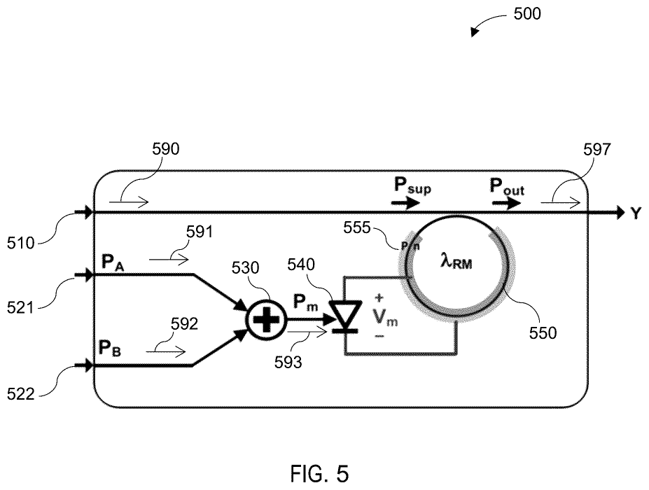

FIG. 5 shows a schematic diagram of an example optical circuit 500, in accordance with various embodiments. The optical circuit 500 includes an optical waveguide 510, a first optical signal input waveguide 521, a second optical signal input waveguide 522, a combiner 530 (sometimes referred to as a coupler, an optical coupler, etc.), a photodetector 540, and an optical resonator 550. The optical circuit 500 of FIG. 5 is simplified for illustrative purposes, and thus, can be implemented as any of various other configurations while remaining within the scope of the present disclosure. In some examples, the optical circuit 500 can include more, fewer, or different components than shown in the figure.

The optical waveguide 510 is configured to receive a continuous wave (CW) optical signal 590 and produce an output signal 597. In some embodiments, the optical waveguide 510 includes an input coupled to the CW optical signal 590. In some embodiments, the optical waveguide 510 is configured to receive the CW optical signal 590 having a first input amplitude (Psup). In some embodiments, the optical waveguide 510 includes an output configured to emit the output signal 597. In some embodiments, the optical waveguide 510 is configured to emit the output signal 597 having an output amplitude (Pout).

In some embodiments, the optical circuit 500 can include a plurality of optical input signal waveguides (e.g., the first optical signal input waveguide 521, the second optical signal input waveguide 522, etc.). In some embodiments, the first optical signal input waveguide 521 is configured to have a first optical input signal 591. For example, the first optical signal input waveguide 521 is configured to receive and/or coupled to the first optical input signal 591. The second optical signal input waveguide 522 is configured to have a second optical input signal 592. For example, the second optical signal input waveguide 522 is configured to receive and/or coupled to the second optical input signal 592. In some embodiments, the plurality of optical input signal waveguides (e.g., the first optical signal input waveguide 521, the second optical signal input waveguide 522, etc.) can be coupled to a plurality of inputs of the optical resonator 550. In some embodiments, the plurality of optical input signal waveguides can be configured to provide (i) a first logic input optical signal (e.g., by the first optical signal input waveguide 521) and (ii) a second logic input optical signal (e.g., by the second optical signal input waveguide 522). For example, the first optical input signal 591 and the second optical input signal 592 can be configured as a logic signal such that (i) the first and second optical input signals have a first optical power corresponding to a logic-high state, (ii) the first and second optical input signals have a second optical power corresponding to a logic-low state, or (iii) the first optical input signal has the first optical power, and the second optical input signal has the second optical power. In some embodiments, the first optical input signal 591 and the second optical input signal 592 have substantially the same wavelength and/or substantially the same phase. As discussed in greater detail below, in some embodiments, the plurality of optical input signal waveguides (e.g., the first optical signal input waveguide 521, the second optical signal input waveguide 522, etc.) can be coupled to the optical resonator 550 through various components (e.g., the optical combiner 530, the photodetector 540, etc.).

In some embodiments, the optical circuit 500 can include the combiner 530 coupled to the plurality of input signal waveguides (e.g., the first optical signal input waveguide 521, the second optical signal input waveguide 522, etc.). The combiner 530 is configured to receive and combine a plurality of input signals from the plurality of input signal waveguides. For example, the combiner 530 can receive the first optical input signal 591 and the second optical input signal 592. The combiner 530 can combine the first optical input signal 591 and the second optical input signal 592 into a combined signal 593. In some embodiments, the combiner 530 may be an optical combiner configured to receive the first optical input signal 591 and the second optical input signal 592 and convert into a combined optical signal. In some embodiments, the combiner 530 may be an optical-electrical combiner configured to receive the first optical input signal 591 and the second optical input signal 592 and convert into a combined electrical signal. In some embodiments, the combiner 530 can include one or more photodiodes. The combiner 530 can produce the combined signal 593 based on the first optical input signal 591 and the second optical input signal 592. In some embodiments, the combiner 530 can be configured as a coupler to extract a fraction of a first optical power P_{A} of the first optical input signal 591 and a second optical power P_{B} of the second optical input signal 592.

In some embodiments, the optical circuit 500 can include the photodetector 540. The photodetector 540 can be configured to receive the combined signal 593. The photodetector 540 can generate a voltage based on the combined signal 593. For example, the photodetector 540 can be configured to convert the combined signal 593 into an electrical voltage signal Vm. In some embodiments, the photodetector 540 can be connected to the combiner 530 to generate an electrical voltage having a magnitude proportional to the fraction of the optical power (e.g., of the first optical power P_{A} of the first optical input signal 591 and the second optical power P_{B} of the second optical input signal 592).

In some embodiments, the optical circuit 500 can include the optical resonator 550. The optical resonator 550 can be coupled to the optical waveguide 510. The optical resonator 550 can be configured to receive the CW optical signal 590 and/or the combined signal 593 (or any optical/electrical signal corresponding thereto, for example, the electrical voltage signal Vm). The optical resonator 550 is configured to change a resonant wavelength of the optical resonator 550 based on an amplitude of the combined signal 593. For example, the photodetector 540 can generate the electrical voltage signal Vm having an amplitude proportional to an amplitude of the combined signal 593. In some embodiments, the optical resonator 550 can be or include, but not limited to, a microring resonator, a tunable microring resonator, etc. In some embodiments, the optical resonator 550 can include a plurality of inputs, each of which can be coupled to each of the plurality of optical signal input waveguides. In some embodiments, the optical resonator 550 can include a semiconductor junction 555 biased by the electrical voltage signal Vm corresponding to the amplitude of the combined signal 593. In some embodiments, the semiconductor junction 555 may be or include, but not limited to, a P-N junction or a PIN junction.

In some embodiments, the optical waveguide 510 can be configured to output, emit, or otherwise provide the output signal 597. For example, the optical waveguide 510 can output the output signal 597 at an output of the optical waveguide 510. The output signal 597 can have an amplitude varying based on the resonant wavelength of the optical resonator 550. In some embodiments, the output signal 597 can be dependent on a location of the resonant wavelength of the optical resonator 550 relative to a wavelength of the CW optical signal 590. In some embodiments, the resonant wavelength of the optical resonator 550 can be tuned by at least the first optical power P_{A} of the first optical input signal 591 and the second optical power P_{B} of the second optical input signal 592.

In some embodiments, the optical waveguide 510 can be configured to emit the output signal 597 based on the electrical voltage signal Vm applied on the optical resonator 550, which can be configured to change the resonant wavelength of the optical resonator 550 based on the electrical voltage signal Vm. In some embodiments, the output signal 597 can have a logic state determined based on a first logical operation of the optical resonator 550 on the first optical input signal 591 (and/or a logic state thereof) and the second optical input signal 592 (and/or a logic state thereof). In some embodiments, the output signal 597 can include the CW optical signal having a first output amplitude. In some embodiments, the first output amplitude can depend on the logic state determined based on the first logical operation of the optical resonator 550 on the first optical input signal 591 (and/or a logic state thereof) and the second optical input signal 592 (and/or a logic state thereof).

In some embodiments, the output signal 597 can have two states associated with a logic-high amplitude and a logic-low amplitude of the CW optical signal 590. Each of the high amplitude and the low amplitude can be less than or equal to the amplitude of the CW optical signal 590. In some embodiments, the output signal 597 can have three states associated with a logic-high amplitude, a logic-low amplitude, and a logic-intermediate amplitude of the CW optical signal 590. Each of the high amplitude, the low amplitude, and the intermediate amplitude can be less than or equal to the amplitude of the CW optical signal 590.

The optical circuits disclosed herein can be configured to perform various logic operations in various manners. In some embodiments, the optical circuits disclosed herein can perform one or more logical operations, including but not limited to, a NAND operation, an OR operation, an XNOR operation, or any combination thereof. In some embodiments, the optical circuits disclosed herein can be connected, optically coupled, or otherwise operatively coupled with another logic component (e.g., a universal optical logic gate, an optical circuit, an optoelectronic circuit, or any component configured to perform a logic operation, such as to provide a one-bit digital full adder, a pattern detector, etc.). In some embodiments, the optical circuits disclosed herein can include a controller configured to various characteristics of the optical circuits. For example, the optical circuits disclosed herein can include a temperature controller configured to increase or decrease a temperature of the microring resonator to maintain the microring resonator at an approximately constant temperature. In some embodiments, the optical circuits disclosed herein can include a power source configured to provide a modulating voltage. For example, such a power source can be coupled to optical signal input waveguides (e.g., the first optical signal input waveguide 521, the second optical signal input waveguide 522, etc.).

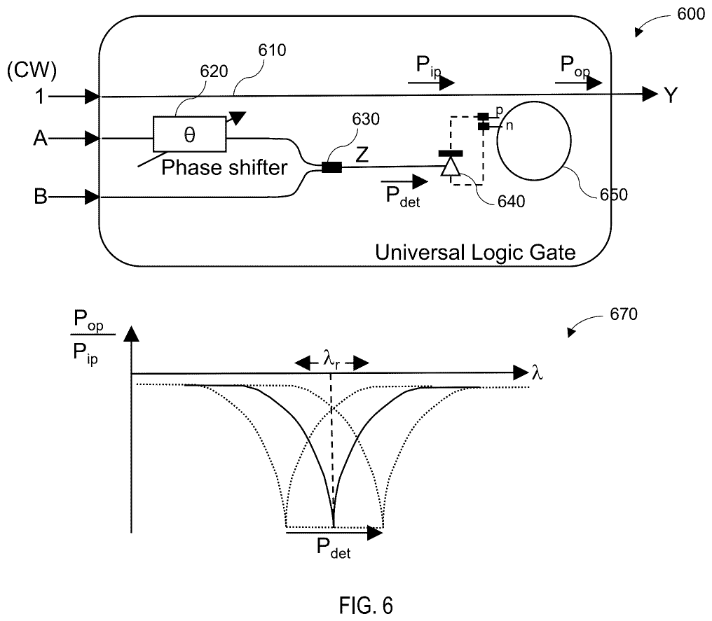

FIG. 6 shows a schematic diagram of an example optical circuit 600 and an example waveform 670, in accordance with various embodiments. The optical circuit 600 and the waveform 670 of FIG. 6 are simplified for illustrative purposes, and thus, can be implemented as any of various other configurations while remaining within the scope of the present disclosure. In some examples, the optical circuit 600 can include more, fewer, or different components than shown in the figure.

Referring to the optical circuit 600, the input to an optical waveguide 610 is a CW optical signal with a constant amplitude and wavelength A. Two other optical signals designated as “A” and “B” serve as inputs to the optical logic gate. In some embodiments, these two optical signals can have a same wavelength. The “A” and “B” optical signals are then combined using an optical combiner 630, and then fed to a photodetector 640 whose output voltage is applied to the PN or PIN of a microring resonator 650. Hence, the resonant wavelength of the microring resonator 650 can depend on the power of the combined “A” and “B” signals. The output optical power can depend on the location of the resonant wavelength relative to the wavelength of the CW signal. Therefore, the output optical power can depend on the power of the combined “A” and “B” optical signals. Assuming “A” and “B” optical signals have the same phase as well as the same wavelength, when both “A” and “B” have small power levels P_{low} (substantially zero and corresponding to “0” logic level), the combined signal can have a small power level. The photodetector output in this case can be very small V_{PD,low} (substantially zero) leaving the resonant frequency of the microring resonator 650 intact (hereon referred to as zero-bias resonant wavelength). When both “A” and “B” have large power levels P_{high} (corresponding to “1” logic level), the power of the combined signal can be 2P_{high}. The photodetector output in this case can have its highest relative value V_{PD,high} causing the most shift in the resonant frequency of the microring resonator 650. When the power level of one of “A” and “B” is P_{low} (“0” logic level) and the power level of the other one is P_{high} (“1” logic level), the power of the combined signal can be P_{high}/2. The photodetector output in this case can have a relatively medium value V_{PD,med} causing a medium shift in the resonant frequency of the microring resonator 650. Note that the terms high, low, and medium are relative and specifically medium does not necessarily correspond to the midway between high and low values. This embodiment can serve as a universal optical digital logic gate in that it can realize fundamental logic operations NAND, OR, XNOR, etc. The optical circuit 600 can be further configured to realize fundamental logic operations XOR, XNOR, NOT, Buffer logic operations, etc. In some embodiments, the optical circuit 600 can include a phase shifter 620. The phase shifter 620 can be configured to modulate the phase of the optical signal “A.” In some embodiments, the optical circuit 600 can include a first phase shifter (e.g., the phase shifter 620) configured to modulate the optical signal “A” and a second phase shifter configured to modulate the optical signal “B.”

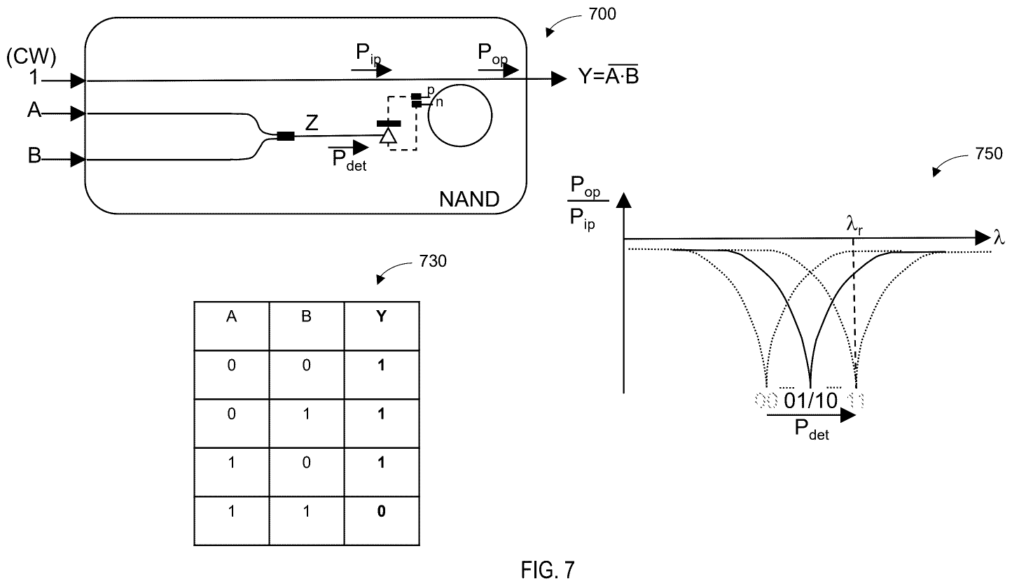

FIG. 7 shows a schematic diagram of an example optical circuit 700, an example truth table 730, and an example waveform 750, in accordance with various embodiments. The optical circuit 700 of FIG. 7 can be configured for NAND logic operation. In this case, the microring resonator is designed so that its resonant wavelength when the “A” and “B” signal levels are low (V_{PD}=V_{PD,low}) called λ₀₀ and when only one of “A” and “B” signal levels is high (V_{PD}=V_{PD,med}) called λ₀₁=λ₁₀ is sufficiently below the CW optical signal wavelength λ_{c}. In these scenarios, the CW optical input signal reaches the output with little attenuation as the transfer functions of the microring resonator at λ_{c} is close to unity (high output power corresponding to logic level “1”). On the other hand, the microring resonator is designed so that its resonant wavelength when both “A” and “B” signal levels are high (V_{PD}=V_{PD,high}) called λ₁₁ is near the CW optical signal wavelength λ_{c} Therefore, in this case, the CW optical signal is significantly attenuated (low output power corresponding to logic level “0”).

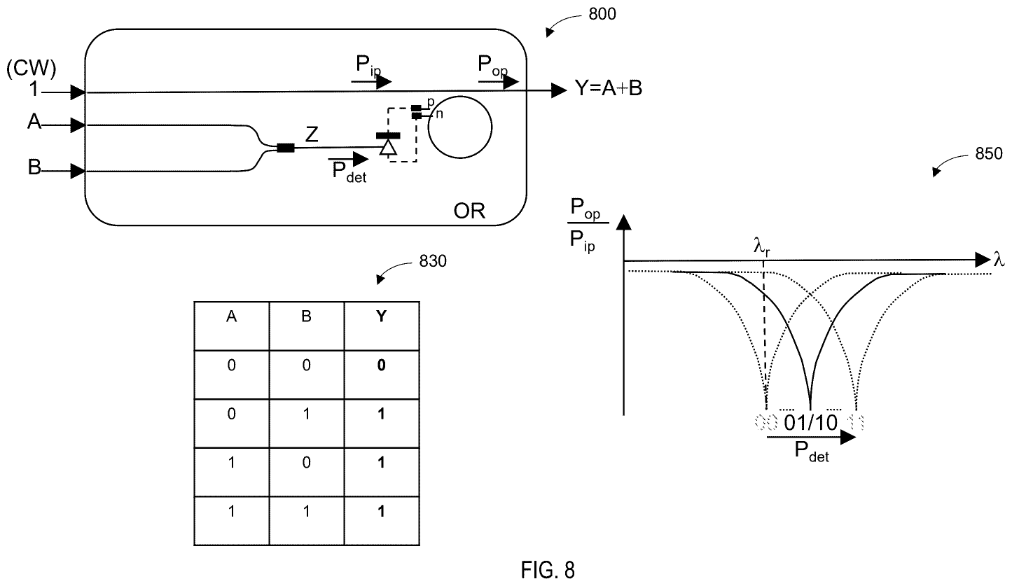

FIG. 8 shows a schematic diagram of an example optical circuit 800, an example truth table 830, and an example waveform 850, in accordance with various embodiments. The optical circuit 800 of FIG. 8 can be configured for OR logic operation. In this case, the microring resonator is designed so that its resonant wavelength when both “A” and “B” signal levels are low (V_{PD}=V_{PD,low}) called λ₀₀ is near the CW optical signal wavelength λ_{c}. In this case, the output power level can then be low (“0” logic level). When either or both of the “A” and “B” signal levels is high, there can be sufficient shift in the resonant wavelength of the microring resonator so that the output power level can be high (“1” logic level).

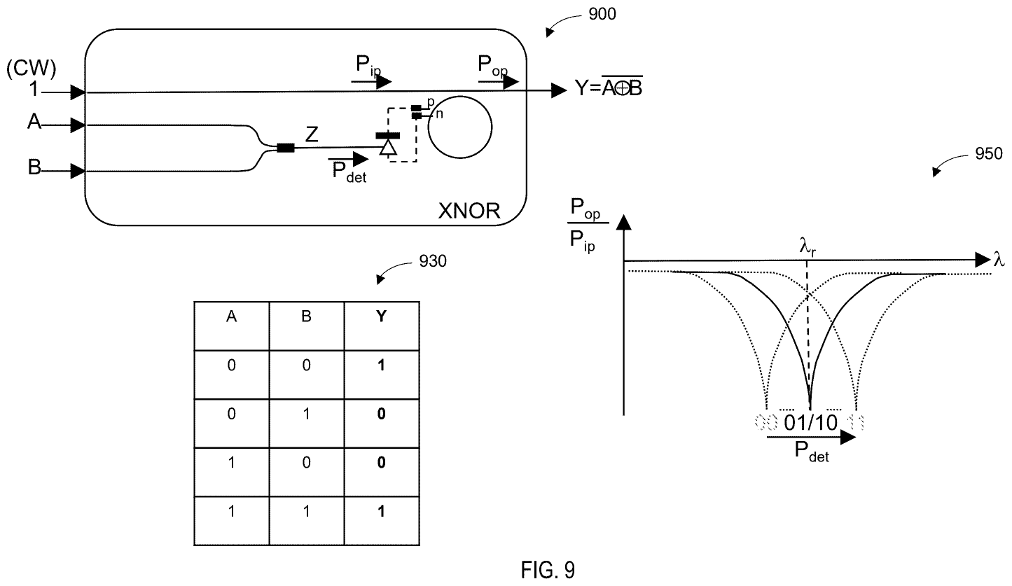

FIG. 9 shows a schematic diagram of an example optical circuit 900, an example truth table 930, and an example waveform 950, in accordance with various embodiments. The optical circuit 900 of FIG. 9 can be configured for XNOR logic operation. In this case, the microring resonator is designed so that its resonant wavelength when only one of “A” and/or “B” signal levels is low (VPD=V_{PD,med}) called λ₁₀=λ₀₁ is near the CW optical signal wavelength λ. In this case, the output power level can then be low (“0” logic level). When both of the “A” and “B” signal levels are high, there can be sufficient shift in the resonant wavelength of the microring resonator (λ₁₁>λ_{c}) so that the output power level can be high (“1” logic level). When both of the “A” and “B” signal levels are low, there can be no/little phase shift in the zero-bias resonant wavelength of the microring resonator (λ_{c}>λ₁₁) so that the output power level can be high (“1” logic level).

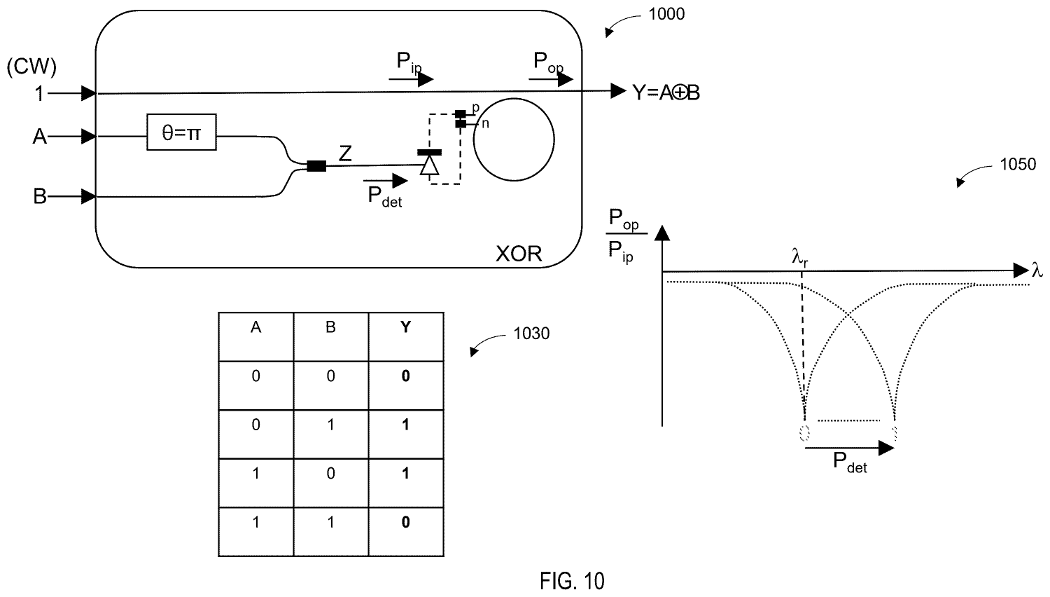

FIG. 10 shows a schematic diagram of an example optical circuit 1000, an example truth table 1030, and an example waveform 1050, in accordance with various embodiments. The optical circuit 1000 of FIG. 10 can be configured for XOR logic operation. In this configuration, the phase of either “A” or “B” signals is shifted by 1800 (or 7E radians) prior to the signal combiner. In other words, the signals that reach the combiner can be out of phase. Therefore, when the “A” and “B” signal levels are either both high or both low (as long as they are equal), the combiner output can have ideally zero power (or very low value) resulting in V_{PD}=V_{PD,low}. The microring resonator is designed to have its zero-bias resonant wavelength λ₀₀ be near the CW optical signal wavelength L. In these scenarios, the output power level can be low (“0” logic level). When only one of “A” or “B” signal levels is high resulting in V_{PD}=V_{PD,med}, the microring resonator resonant wavelength shifts to a value λ₁₀=λ₀₁ that is sufficiently far from λₑ The output power level in this case can then be high (“1” logic level).

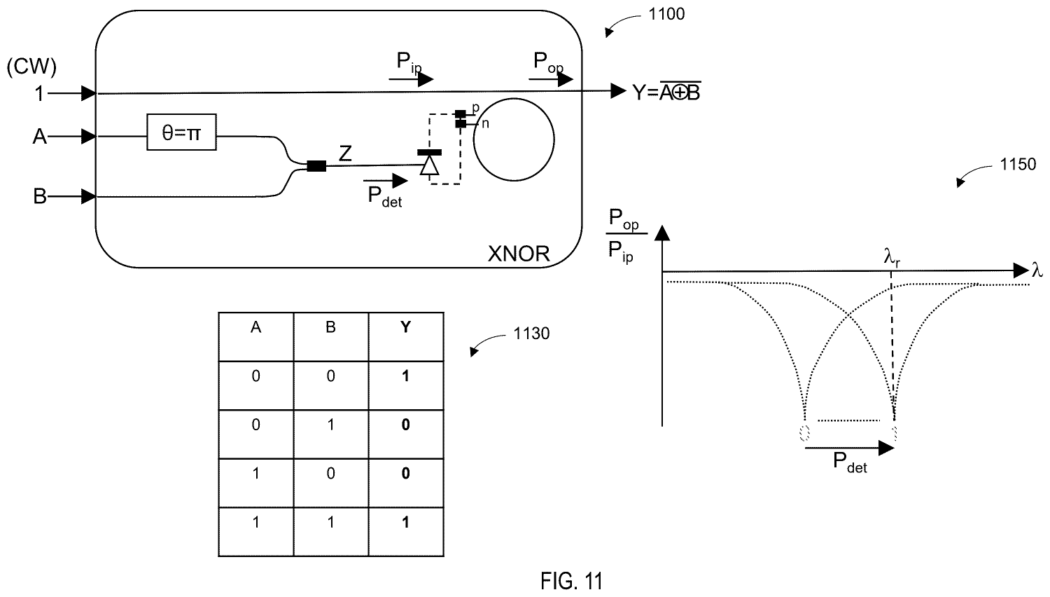

FIG. 11 shows a schematic diagram of an example optical circuit 1100, an example truth table 1130, and an example waveform 1150, in accordance with various embodiments. The optical circuit 1100 of FIG. 11 can be configured for XNOR logic operation. In this configuration, the phase of either “A” or “B” signals is shifted by 180° (or π radians) prior to the signal combiner. In other words, the signals that reach the combiner can be out of phase. Therefore, when the “A” and “B” signal levels are either both high or both low (as long as they are equal), the combiner output can have ideally zero power (or very low value) resulting in V_{PD}=V_{PD,low}. The microring resonator is designed to have its zero-bias resonant wavelength λ₀₀ sufficiently away from the CW optical signal wavelength λ_{c}. In these scenarios, the output power level can be high (“1” logic level). When only one of “A” or “B” signal levels is high resulting in V_{PD}=V_{PD,med}, the microring resonator resonant wavelength shifts to a value λ₁₀=λ₀₁ that is near the CW optical signal wavelength Δ_{c}. The output power level in this case can then be low (“0” logic level).

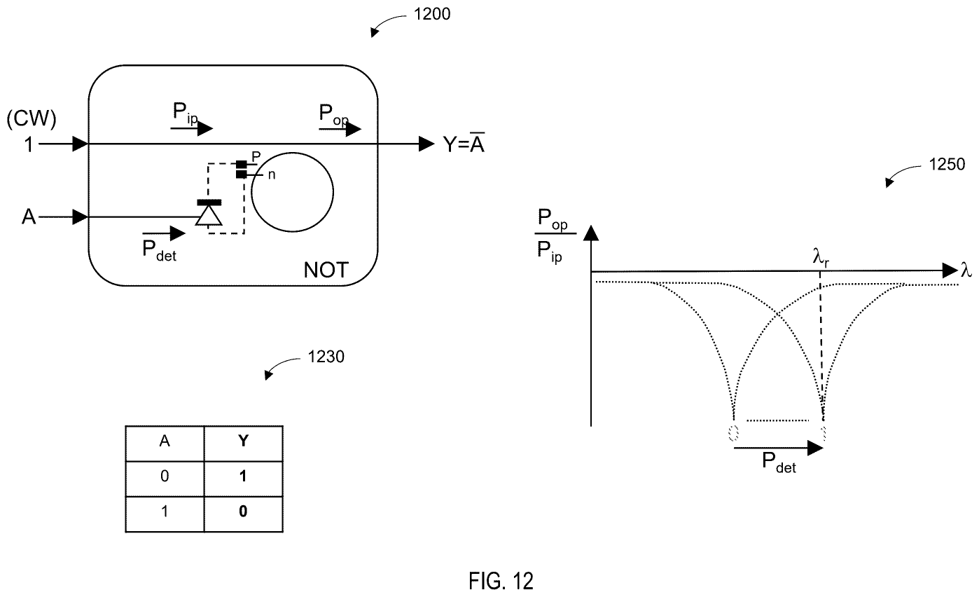

FIG. 12 shows a schematic diagram of an example optical circuit 1200, an example truth table 1230, and an example waveform 1250, in accordance with various embodiments. The optical circuit 1200 of FIG. 12 can be configured for NOT logic operation. Only one input optical signal “A” is applied to the photodetector. The zero-bias resonant wavelength of the microring resonator (corresponding to the case where “A” signal level is low) is designed to be sufficiently away from the CW optical signal wavelength λ_{c}. The output power level in this case can then be high (“1” logic level). When the signal level “A” is high, the resonant wavelength of the microring resonator shifts to a value that is near the CW optical signal wavelength λ_{c}. The output power level in this case can then be low (“0” logic level).

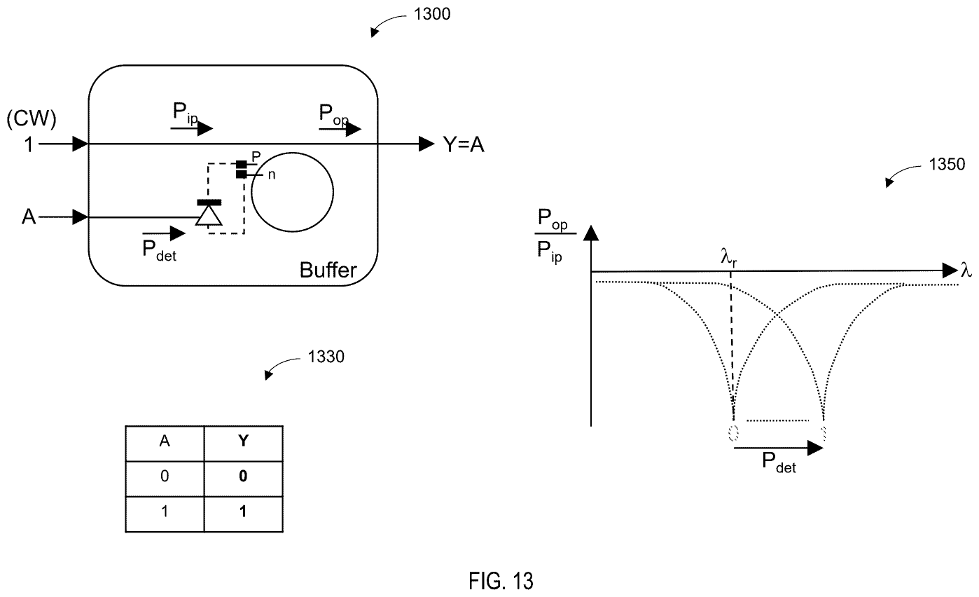

FIG. 13 shows a schematic diagram of an example optical circuit 1300, an example truth table 1330, and an example waveform 1350, in accordance with various embodiments. The optical circuit 1300 of FIG. 13 can be configured for Buffer logic operation. In this case, the output logic simply follows the input logic. This block can be used to bring the optical power levels that might have been attenuated back to the desired logic levels. Only one input optical signal “A” is applied to the photodetector. The zero-bias resonant wavelength of the microring resonator (corresponding to the case where “A” signal level is low) is set to be near the CW optical signal wavelength λ_{c}. Therefore, when the level of “A” is low, the output is also low (“0” logic). When the signal level “A” is high, the resonant wavelength of the microring resonator shifts to a value that is further away from the CW optical signal wavelength λ_{c}. The output power level in this case can then be high (“1” logic level).

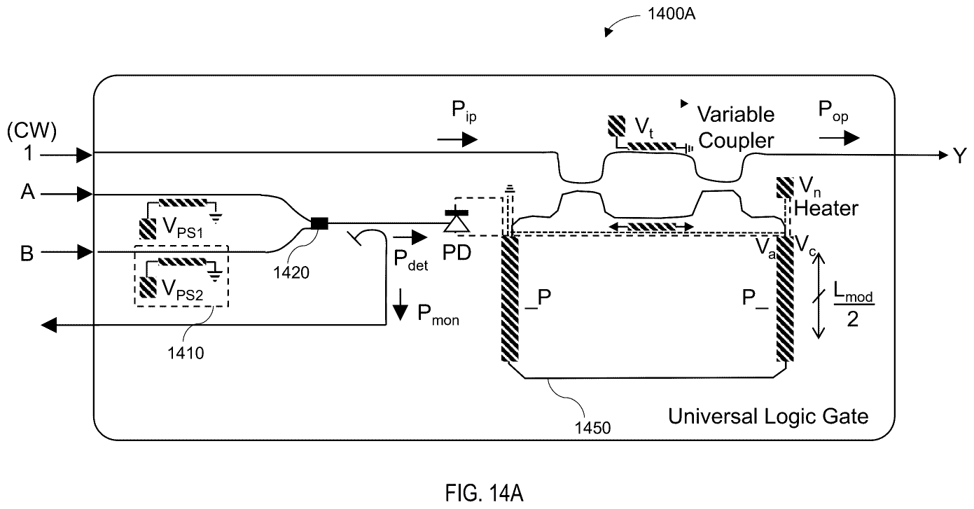

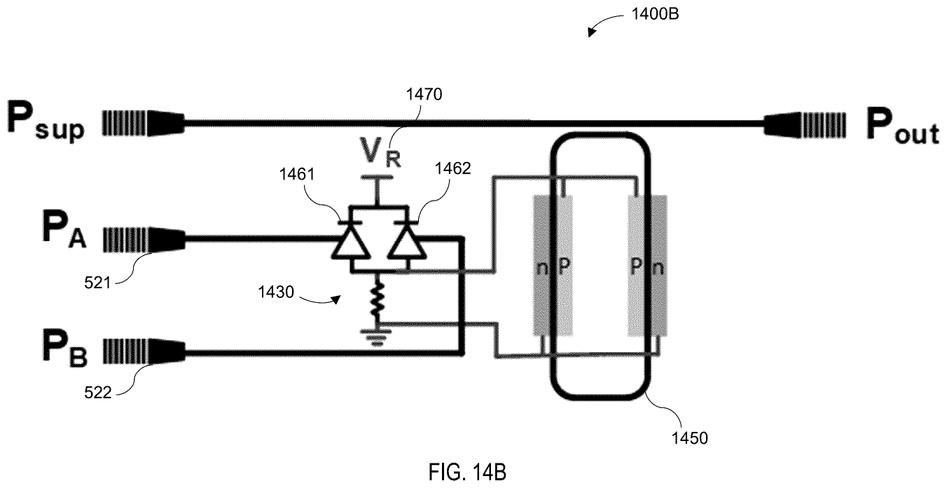

It should be mentioned that the resonant wavelength of the microring resonators changes with process variations and depends on temperature. Therefore, in practice, the resonant wavelengths of microring resonators are stabilized using temperature control circuitry. Furthermore, in practice, process imperfections might affect the relative phases of signals in the universal gate. Controllable optical phase shifters can be used to adjust the relative phases appropriately. FIG. 14A shows a schematic diagram of an example optical circuit 1400A, in accordance with various embodiments. In some embodiments, the optical circuit 1400A may be substantially similar to or incorporate features of the optical circuit 500, etc. For example, the optical circuit 1400A includes a phase shifter 1410, an optical resonator 1450, etc. The optical circuit 1400A of FIG. 14A is simplified for illustrative purposes, and thus, can be implemented as any of various other configurations while remaining within the scope of the present disclosure. In some examples, the optical circuit 1400A can include more, fewer, or different components than shown in FIG. 14A.

The phase shifter 1410 can be configured to adjust the relative phases between “A” and “B” input signals. In some embodiments, the optical circuit 1400A can include a directional coupler 1420. The directional coupler 1420 can be configured to monitor a phase shift of the input signals, a phase difference between the input signals, etc.

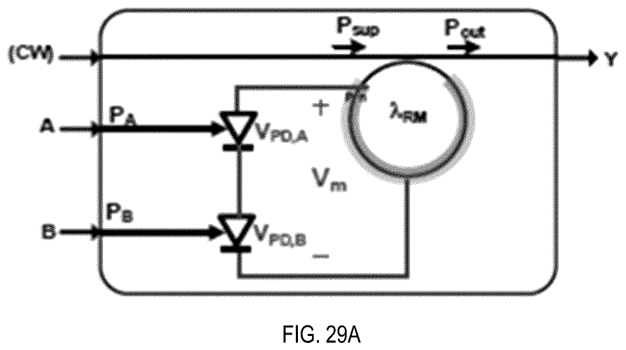

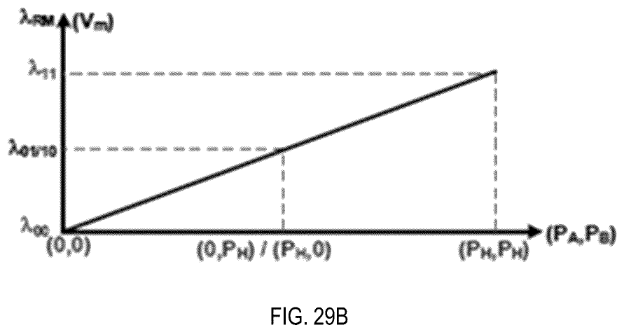

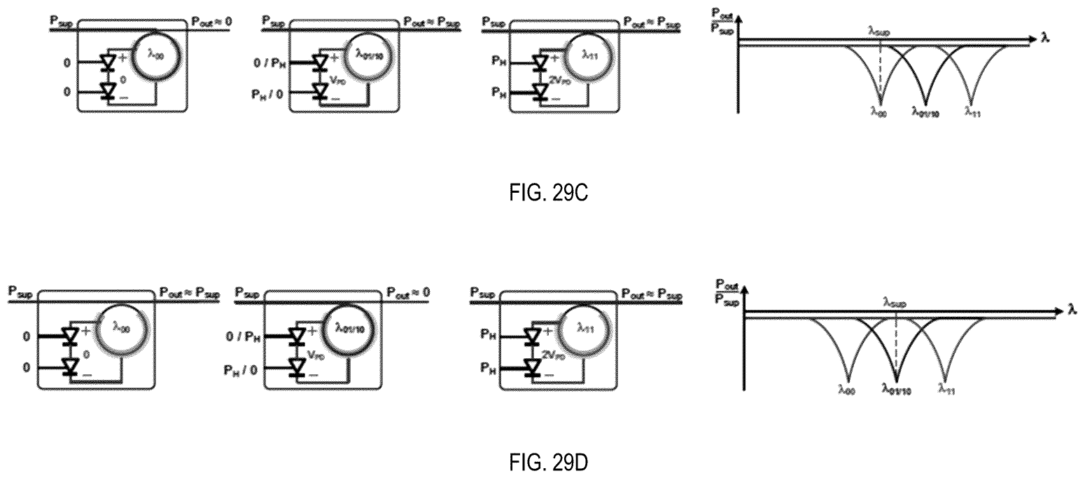

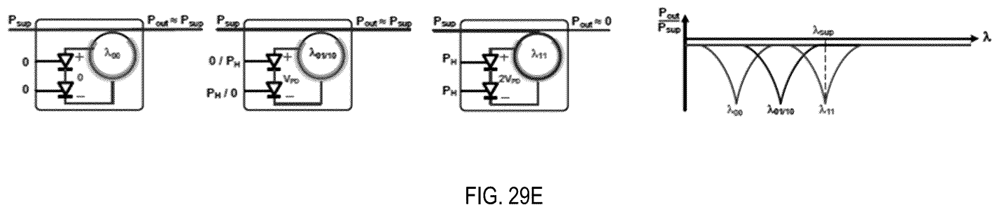

FIG. 14B shows a schematic diagram of an example optical circuit 1400B, in accordance with various embodiments. In some embodiments, the optical circuit 1400B may be substantially similar to or incorporate features of the optical circuit 500, etc. For example, the optical circuit 1400B alternatively includes a combiner 1430, as opposed to the optical circuit 500. In some embodiments, the combiner 1430 can include a first photodiode 1461, a second photodiode 1462, a power source 1470, etc. The optical circuit 1400B of FIG. 14B is simplified for illustrative purposes, and thus, can be implemented as any of various other configurations while remaining within the scope of the present disclosure. In some examples, the optical circuit 1400B can include more, fewer, or different components than shown in FIG. 14B. For example, the combiner 1430 may omit the power source 1470 (e.g., as shown in FIG. 29A).

In some embodiments, the combiner 1430 can be coupled to the first optical input signal waveguide 521 and the second optical input signal waveguide 522 to receive the first and second optical input signals and combine the first and second optical input signals into a combined input signal. In some embodiments, the combined input signal may be a combined electrical signal. In some embodiments, the combiner 1430 includes the first photodiode 1461 coupled to the first optical signal input waveguide 521 and the second photodiode 1462 coupled to the second optical signal input waveguide 522. In some embodiments, the combiner 1430 is configured to provide a first electrical signal and a second electrical signal based on the first optical input signal and the second optical input signal, respectively. For example, the combiner 1430 can convert the first optical signal into the first electrical signal, convert the second optical signal into the second electrical signal, and combine the first electrical signal and the second electrical signal into the combined input signal.

The power source 1470 is coupled to the first photodiode 1461 and the second photodiode 1462. In some embodiments, the power source 1470 can be configured to provide a modulating voltage V_{R}. The optical resonator 550 can be configured to receive the first electrical signal (e.g., from the first optical signal input waveguide 521, through the first photodiode 1461), the second electrical signal (from the second optical signal input waveguide 522, through the second photodiode 1462), and the modulating voltage V_{R}. This allows for high speed operation of the optical logic gates, as discussed in greater detail below.

In some embodiments, the optical circuit 1400A can include a temperature controller (not shown). The temperature controller can be coupled to and/or be included in one or more components of the optical circuit 1400A, the optical circuit 1400B, etc. For example, the temperature controller can be connected to and/or included in the phase shifter 1410, the directional coupler 1420, a variable coupler, the optical resonator 1450, circuitry including the power source 1470, etc. The temperature controller can be configured to increase or decrease a temperature of one or more components of the optical circuit 1400A, the optical circuit 1400B, etc. For example, the temperature controller can be configured to increase or decrease a temperature of the optical resonator 1450 to maintain the optical resonator 1450 at an approximately constant temperature.

In some embodiments, the optical resonator 1450 can be coupled to the optical waveguide (e.g., through the combiner 1430) and configured to receive the combined input signal. The optical resonator 1450 can be configured to change a resonant wavelength of the optical resonator 1450 based on an amplitude of the combined input signal. In some embodiments, the optical resonator 1450 includes a microring resonator having a semiconductor junction biased by an electrical voltage corresponding to the amplitude of the combined input signal. The optical waveguide can be configured to output an output signal at an output of the optical waveguide, the output signal having an amplitude varying based on the resonant wavelength of the optical resonator 1450.

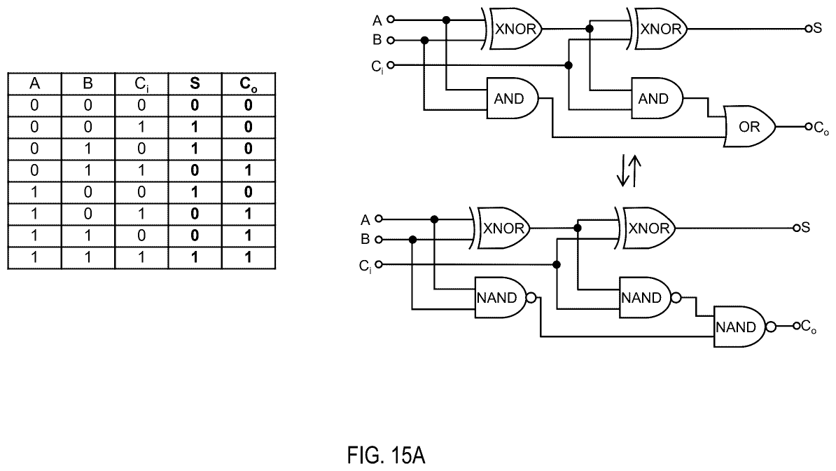

Optical digital logic gates disclosed herein can be used to realize complex optical digital circuitry and functions in a way that is analogous to digital logic gates creating a complex digital circuit and function. As a non-limiting example, a digital 1-bit full adder is shown in FIG. 15A along with an associated truth table. As with digital logic circuits, the optical circuits disclosed herein can include a plurality of optical circuits that are optically coupled with each other in various manners (e.g., in series, in parallel, etc.).

As a non-limiting example, a pattern detector is shown in FIG. 15B. As with digital logic circuits, the optical circuits disclosed herein can include a plurality of optical circuits that are optically coupled with each other in various manners (e.g., in series, in parallel, etc.). The pattern detector of FIG. 15B can be used in various applications (e.g., optical packet switching). For example, the optical circuit of FIG. 15B can be configured to recognize a packet's header and route the packet accordingly. In some embodiments, as shown in FIG. 15B, the optical circuit can include optical XNOR or XOR gates to implement a pattern detection. For example, the output of the XOR gate can be “0” (e.g., minimum output power) when both logic inputs are the same, and vice versa for the XNOR gate. The output power can be “1” (e.g., maximum) when the logic inputs are identical. In some embodiments, every window of N-bit of the input data can be de-serialized using a set of scaled delay line and MMI splitters network, then compared with a targeted pattern using N parallel XNOR. The target pattern can be generated using a CW laser, splitters, and N parallel optical switches, etc. Then it can be changed by controlling the transmission of the optical switches. The output of the XNOR gates can be combined using a MMI combiner network. As the power can be combined coherently, the phase of the XNOR outputs can be calibrated using phase shifters.

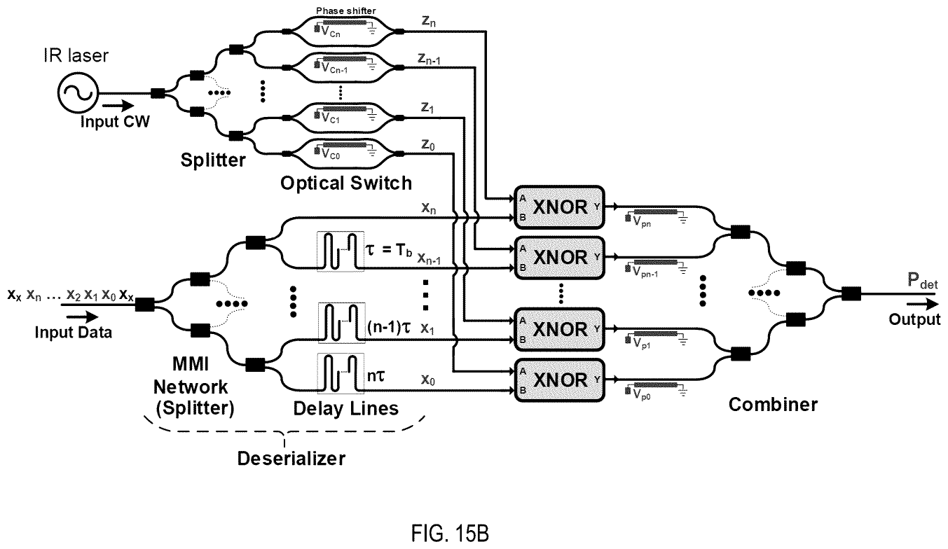

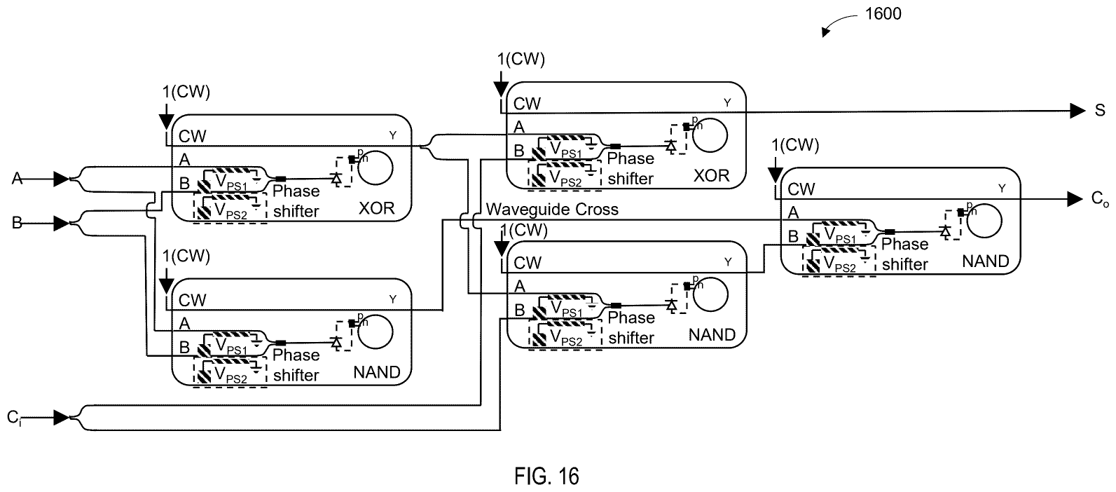

FIG. 16 shows a schematic diagram of an example optical circuit 1600, in accordance with various embodiments. In some embodiments, the optical circuit 1600 may be substantially similar to or incorporate features of the optical circuit 500, the optical circuit 1400A, etc. The optical circuit 1600 includes a plurality of optical circuits (e.g., the optical circuits 1400A) arranged and/or optically coupled to form a logic circuit (e.g., an optical 1-bit full adder). The optical circuit 1600 of FIG. 16 is simplified for illustrative purposes, and thus, can be implemented as any of various other configurations while remaining within the scope of the present disclosure. In some examples, the optical circuit 1600 can include more, fewer, or different components than shown in FIG. 16.

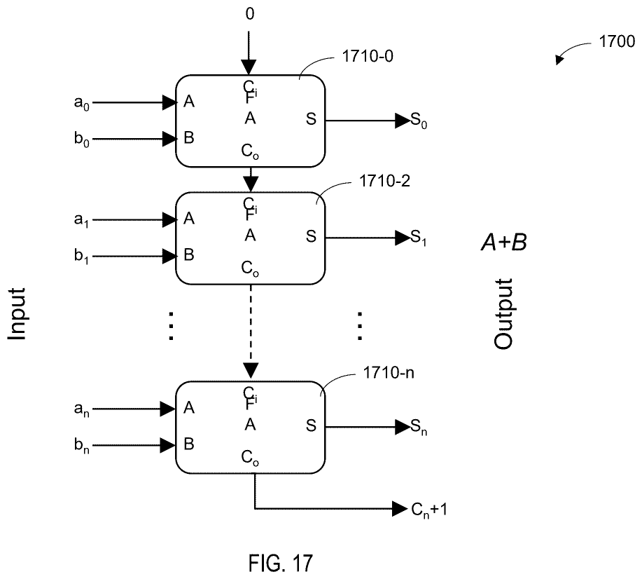

In some embodiments, the optical circuit 1600, which can be configured to serve as a 1-bit full adder, can form a multi-bit full adder. FIG. 17 shows a schematic diagram of an example optical circuit 1700, in accordance with various embodiments. In some embodiments, the optical circuit 1700 may be substantially similar to or incorporate features of the optical circuit 500, the optical circuit 1600, etc. The optical circuit 1700 includes a plurality of optical circuits 1710-0, 1710-2, . . . , 1710-n (e.g., the optical circuits 1600) arranged and/or optically coupled to form a logic circuit (e.g., an optical multi-bit full adder). The optical circuit 1700 of FIG. 17 is simplified for illustrative purposes, and thus, can be implemented as any of various other configurations while remaining within the scope of the present disclosure. In some examples, the optical circuit 1700 can include more, fewer, or different components than shown in FIG. 17. In some embodiments, the optical circuit 1700 can be configured such that the input and output are multi-bit parallel signals (e.g., as shown).

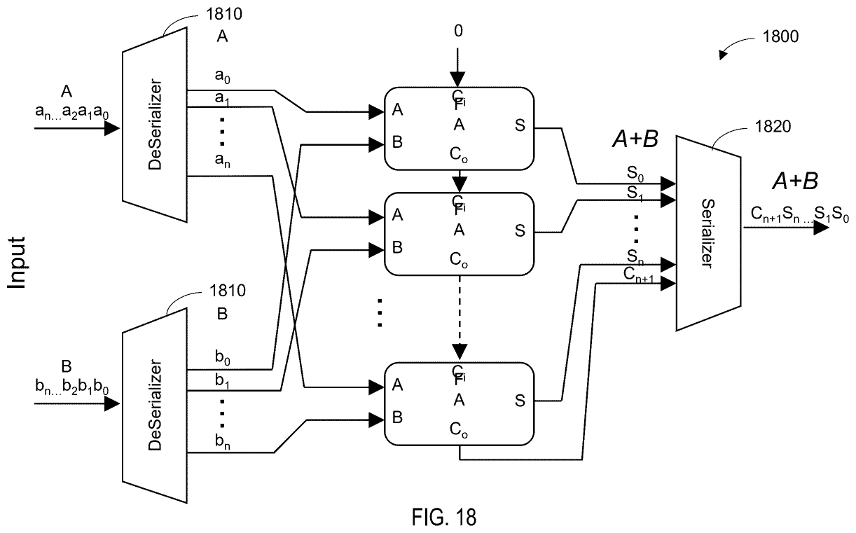

In some embodiments, the optical circuit 1700 can be operatively coupled with a serializer, a deserializer, etc. FIG. 18 shows a schematic diagram of an example optical circuit 1800, in accordance with various embodiments. In some embodiments, the optical circuit 1800 may be substantially similar to or incorporate features of the optical circuit 1800, etc. For example, the optical circuit 1800 additionally includes deserializers 1810 and a serializer 1820, as opposed to the optical circuit 1700. In some embodiments, the optical circuit 1700 can be configured such that the input bit streams can be configured to arrive serially, and “n+1” consecutive bits in the serial bit stream correspond to an n-bit number. In this scenario, the serial inputs either can be converted to parallel format prior to the full adder, and then converted back again to serial format at the full adder output.

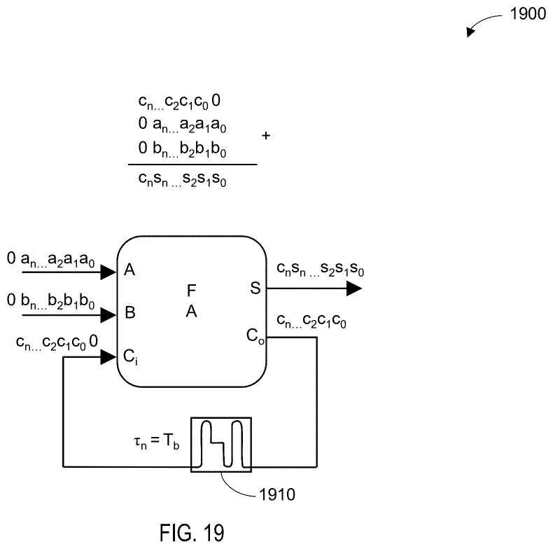

In some embodiments, the optical circuit 1600, which can be configured to serve as a 1-bit full adder, can form a 1-bit full adder configured to output a “Carry” bit. FIG. 19 shows a schematic diagram of an example optical circuit 1900, in accordance with various embodiments. In some embodiments, the optical circuit 1900 may be substantially similar to or incorporate features of the optical circuit 500, the optical circuit 1600, etc. For example, the optical circuit 1900 can additionally include a delay circuit 1910, as opposed to the optical circuit 1600. The delay circuit 1910 can be configured to provide a delay equal to the bit period to send the output “Carry” bit at the full-adder output and to the input “Carry” at the 1-bit full-adder input. The optical circuit 1900 of FIG. 19 is simplified for illustrative purposes, and thus, can be implemented as any of various other configurations while remaining within the scope of the present disclosure. In some examples, the optical circuit 1900 can include more, fewer, or different components than shown in FIG. 19.

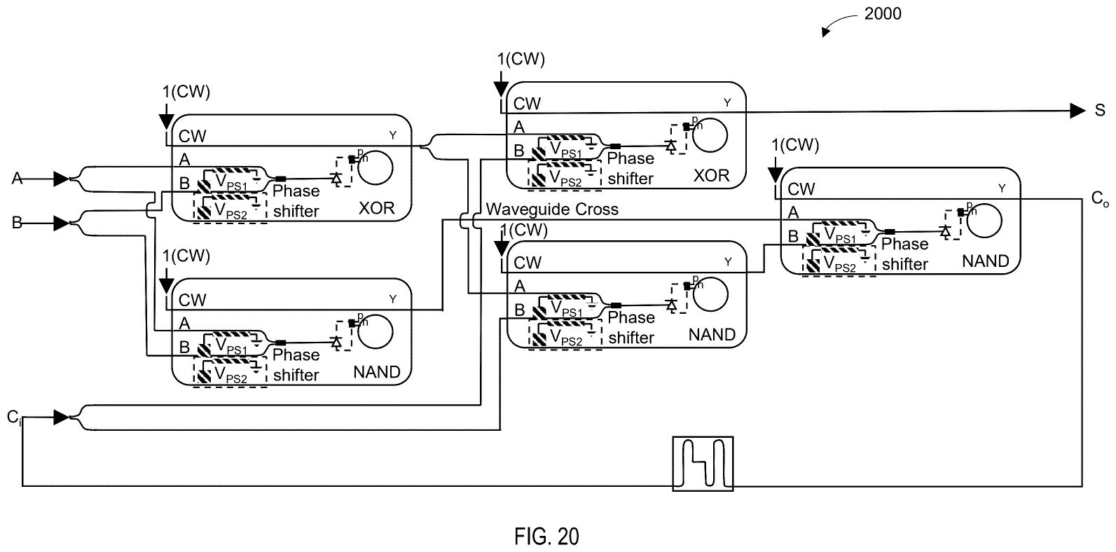

FIG. 20 shows a schematic diagram of an example optical circuit 2000, in accordance with various embodiments. In some embodiments, the optical circuit 2000 may be substantially similar to or incorporate features of the optical circuit 500, the optical circuit 1600, the optical circuit 1900, etc. For example, the optical circuit 2000 can combine the features of the optical circuit 1600 and of the optical circuit 1900 to form an optical multi-bit digital full adder operating on serial inputs. The optical circuit 2000 of FIG. 20 is simplified for illustrative purposes, and thus, can be implemented as any of various other configurations while remaining within the scope of the present disclosure. In some examples, the optical circuit 2000 can include more, fewer, or different components than shown in FIG. 20. Any other complex digital circuits can also be created using one or more components of the optical circuits disclosed here, without departing the scope and spirit of the present disclosure.

B. Universal all-Optical Zero-Bias Logic Gates in Silicon Photonics

The optical circuits, as disclosed herein can be realized in a commercial foundry silicon photonics process. Microring resonator modulator and zero-biased stacked photodiodes can be used to create the required optical input-output nonlinear transfer function for optical gate realizations. Several logic gate functions, specifically NOR which is a universal logic gate that can be used to implement any logic, are demonstrated. Logic operation on 10 Mbps data streams is demonstrated using universal optical logic gates without requiring any electrical supply voltage. The total optical power for one such universal logic gate is 160 μW.

Digital logic is ubiquitous in computing and signal processing platforms. The reduction of size and energy consumption of electronic digital logic gates is the main driver behind CMOS technology scaling. From this perspective, it is hard to conceive alternate technologies that can outperform electronic digital gates. However, there are applications where electronic processing of information is not possible or easy due to the difficulty in routing electrical signals or accessing electrical power supply, electromagnetic interference, or security concerns. Data can be transferred to remote locations over optical fibers without much fear of electromagnetic interference. It would be useful to be able to process this data in the optical domain without requiring electronics circuitry or power supply.

Optical information processing may occur in analog or digital domains. There is recent emphasis on analog optical processors that can realize vector-vector, vector-matrix, or matrix-matrix multiplication at high speeds and low energy costs. Digital optical processors naturally require digital logic gates. There have been several past attempts to realize optical digital logic gates. There are two primary approaches to implementing optical logic gates, namely, all-optical approach and optical-directed logic approach.

In all-optical digital logic gates, the operands and the logic operation are in the optical domain. Past implementations of all optical logic primarily depend on coherent addition/subtraction of optical fields using for instance a multimode interferometer (MMI) or topology optimized inverse designed structures. An interferometer with a 180° phase shifter in one arm functions as an exclusive or (XOR) gate. Assume the two inputs are in-phase coherent optical signals that may have either zero or P_{H} power levels corresponding to “0” and “1” logic levels. The output power level can be zero when both inputs have the same power (corresponding to “00” or “11” logic levels) and can be P_{H}/2 when only one input has P_{H} power (corresponding to “01” and “10” logic levels). In other words, the output levels of zero and P_{H}/2 correspond to “0” and “1” logic levels. The main drawback of these approaches is that the gate function depends on the relative phases of the input optical signals. On the other hand, the phase of the gate output depends on the inputs. For instance, in the aforementioned XOR gate, the output phases of the two cases corresponding to “01” and “10” logic levels can have 180° phase difference. In other words, the “01” and “10” outputs are not truly the same which may be problematic for cascading logic gates. The other shortcoming of this approach is that the output high logic level (P_{H}/2 in the past example) is always lower than the input high logic level (P_{H}). This too causes problems when gates are cascaded. Electronic digital logic gates rely on the nonlinear input-output transfer function. Optical nonlinearity, such as two-photon absorption, may be used to create digital logic gates. These approaches typically require relatively high optical power levels. The optical directed logic on the other hand operates with electrical operands and optical logic operation. This is mainly constructed using a network of micro-ring/disk or Mach-Zehnder interferometers (MZI) that act as switch and controlled by the electrical operands. In a hybrid approach, the electrical operands of the directed-logic core are generated from optical signals.

As discussed herein, demonstrated are optical-input optical-output logic gates that leverage an internal optical-electrical conversion without using any electrical supply voltage or control signal. Specifically, the universal logic gate NOR, from which any digital logic circuit can be demonstrated, using a commercial foundry silicon photonics process. The optical gate operates at 10 Mbps while consuming 160 μW of total optical power.

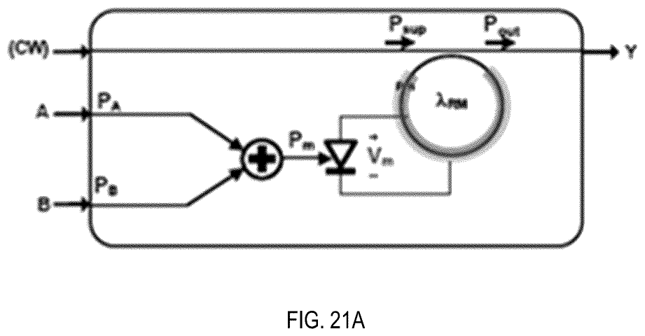

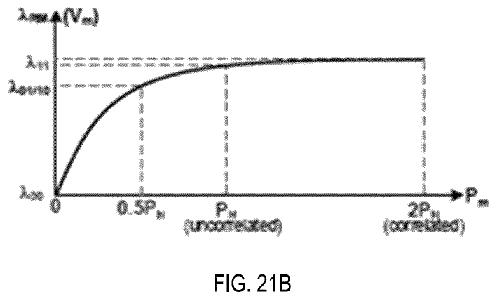

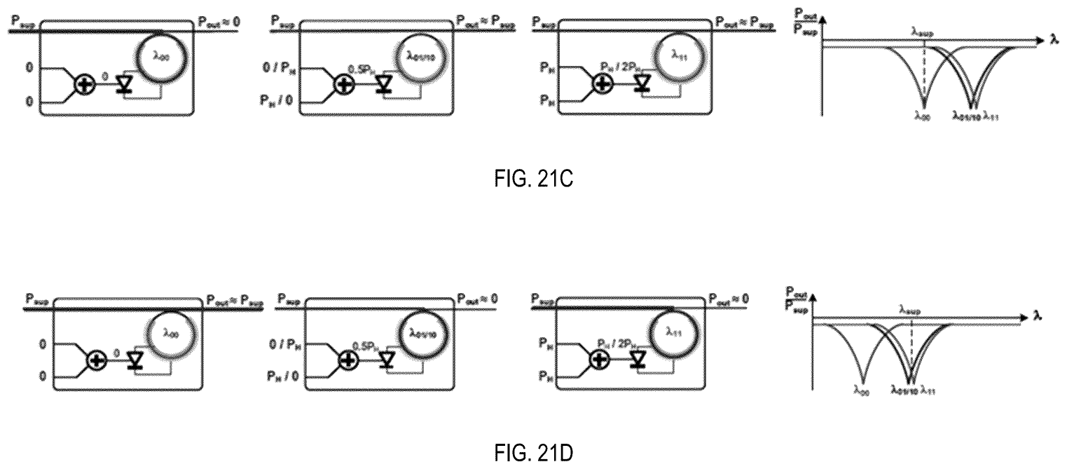

The proposed all-optical universal logic gate shown in FIG. 21A has two optical inputs (operands), one optical output, and one continuous wave (CW) optical source acting as the “supply” that is analogous to the voltage supply of an electronic digital logic gate. The optical inputs can have power levels of 0 and P_{H} corresponding to “0” and “1” logic levels. The output logic level can depend on the combination of the two input signal levels and the “supply” level. The optical power of the combined input signals, once converted to an electrical voltage through a photovoltaic (zero-biased) photodetector, determines the resonant wavelength of a microring modulator that is coupled to the “supply” line. This resonance shift can then determine whether the “supply” signal is coupled to the output or not. This optical gate does not require any electronic supply voltage source.

Assuming the unmodulated resonant wavelength of the microring modulator (sum) is equal to the wavelength of the “supply” line (λₛᵤₚ), in the absence of any input signal (both at zero power or “0” logic level), the “supply” does not couple to the output and the output power level can be zero or “0” logic level. Once either or both input signals are present (logic “1”), the photovoltaic photodiode can generate a sufficiently high voltage to shift the resonant wavelength of the microring modulator so that the “supply” line couples to the output and the output power level can be at the “1” logic level. This can emulate an OR logic function (FIG. 21C).

Alternatively, assume the unmodulated resonant wavelength of the microring modulator is detuned, but close enough, from the wavelength of the “supply” line. In this case, in the absence of any input signal (both at zero power or “0” logic level), the “supply” couples to the output resulting in “1” logic level. Once either or both input signals are present (logic “1”), the voltage generated by the photovoltaic photodiode can shift the resonant wavelength of the microring modulator to be equal or very close to the wavelength of the “supply” line. Therefore, the “supply” signal does not couple to the output resulting in zero output power corresponding to “0” logic level. This can emulate a NOR logic function (FIG. 21D). The same gate with only one applied input (single operand) can act as a NOT logic function.

Naturally, proper gate operation can depend on the appropriate resonant shift of the microring modulator as a function of input signal power levels. In fact, the OR and NOR gates explained above, in some embodiments, require the resonant shifts corresponding to the presence of optical power at one or both inputs to be nearly the same. The photovoltaic photodiode offers a nonlinear response between its input optical power level and its output generated voltage. On the other hand, the resonant wavelength shift of the microring modulator is almost a linear function of the modulating voltage. Therefore, the transfer function between the optical power of the combined input signals and the resonant wavelength of the microring modulator is nonlinear (FIG. 21B).

The optical inputs (operands) may be combined in the optical or electrical domains. In the case of optical combining, coherent and incoherent cases may be considered. In the coherent case, both inputs are generated from the same optical source. The output power level of a coherent combiner depends on the relative phases of the two inputs. The output power can be zero when both inputs have zero power, P_{H}/2 when only one input is nonzero at P_{H} power level, and a value that can be anywhere between zero and 2P_{H} when both inputs are nonzero at P_{H} power levels with a relative phase shift. The combined power is equal to zero (2P_{H}) for 180° (0°) phase shift between the two inputs. A phase modulator prior to the combiner is hence necessary in the case of coherent input sources to ensure that the two coherent inputs are added in phase for the proper operation of the OR and NOR gates. If the two inputs are derived from independent sources, the output power of the incoherent combiner can be 0 when both inputs have zero power, P_{H}/2 when only one input is nonzero at P_{H} power level, and P_{H} when both inputs are nonzero at P_{H} power level. As explained above, in the case of optical power combining, the resonant wavelength shift of the microring modulator is a nonlinear function of the combined power levels. Specifically, the resonant shifts caused by output power levels P_{H}/2, P_{H}, and 2P_{H} are not far (FIG. 21B).

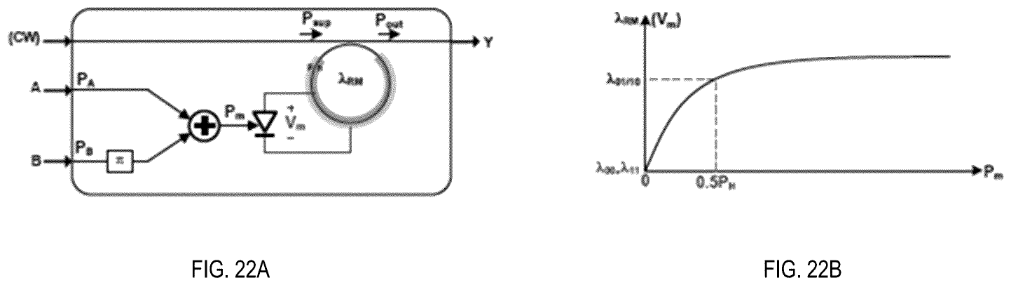

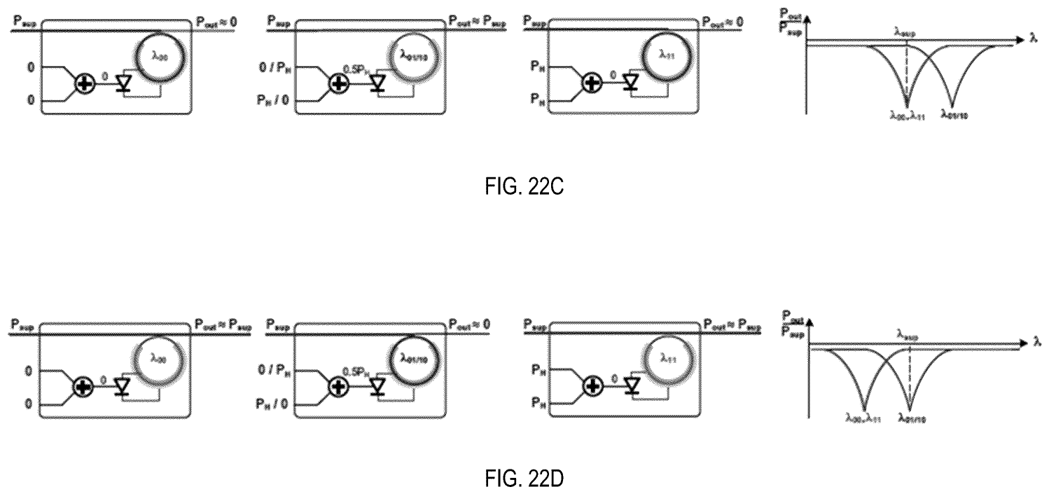

In the case of optical power combining with coherent inputs, the necessary phase modulator prior to power combiner may be adjusted judiciously to create XOR and XNOR gate functions. Specifically, imagine the phase modulator creates 180° phase shift between the two signals at the combiner input (FIG. 22A). This means that the coherent combiner output when both input power levels are equal (either at zero or P_{H}) is equal to zero. Therefore, the resonant wavelength of the microring modulator (FIG. 22B) and the logic gate output can be the same when both inputs are either zero or PH (logic levels 00 or 11). In the first case, assume the unmodulated resonant wavelength of the microring modulator is equal to the wavelength of the “supply” line. The “supply” signal may not couple to the output when both input signals have the same power level (output logic 0). The “supply” signal can couple to the output when only one of the inputs has nonzero power, due to the resonant shift of the microring modulator, resulting in output logic 1. This can emulate the XOR gate function (FIG. 22C). In a second case, when the unmodulated resonant wavelength of the microring modulator is unequal, but close, to the wavelength of the “supply” line, the “supply” signal can couple to the output when both input power levels are equal resulting in output logic level 1. When only one input has power, the resonant wavelength of the microring modulator can shift in a way that the “supply” does not couple to the output resulting in logic level 0. This can emulate the XNOR gate function (FIG. 22D).

The zero-bias universal optical logic gates can be implemented in the Tower Semiconductor PH18 MA foundry silicon photonics process. The 220 nm thick silicon layer is on top of a 3 μm buried silicon oxide layer. The waveguide structure in most of the devices is a single-mode strip silicon waveguide with 500 nm width. Grating couplers are used to couple the light into and out of the chip.

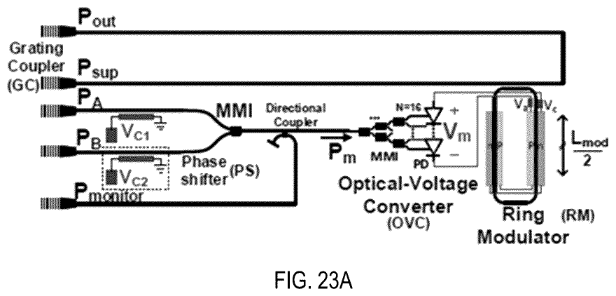

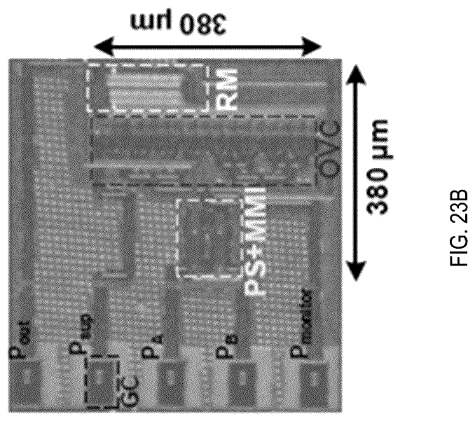

The schematic diagram of the logic gate is shown in FIG. 23A. The 2×1 combiner is realized using multi-mode interferometer (MMI) structure. The MMI has compact dimension of 2 μm×3.5 μm and measured excess loss of 0.15 dB. In order to set the phase relation of the input logic in case of the two operands (P_{A} and P_{B}) with correlated carriers, geometrically-optimized (low loss), heat-reuse (energy efficient) thermo-optic phase shifters are used (design B in). One phase shifter is needed to set the phase difference between the two inputs carriers and the other one is just a dummy to match the loss and delay between the two paths. The measured loss of the phase shifter is 1 dB and the P_{π} is 2.5 mW. A 90:10 directional coupler is used to tap −10 dB of the combined input logic power Pₘₒₙᵢₜₒᵣ for monitoring purpose.

The photodiode in photovoltaic mode operates in open circuit configuration (or capacitive load) where maximum power efficiency is achieved. Resistive loads less than the internal resistance of the photodiode reduce the generated output voltage significantly. This internal resistance limits the intrinsic speed of the photovoltaic photodiode to 10s of MHz depends on the technology and the device size. The photovoltaic photodiode is more suitable to drive charge depletion optical modulators and not charge injection or thermo-optic modulators as the latter two draw currents (resistive load). The main design challenge when using a photovoltaic photodiode is the limited output voltage range. The maximum voltage generated across one photovoltaic diode is limited by the photodiode open circuit voltage; this value is around 0.35 V for the germanium photodiode that is used in this technology. This issue can be solved by connecting the photodiodes in series. In this case, the voltages across the series-connected diodes are added and the maximum output voltage is extended. An MMI-based optical distribution network is used to deliver the input optical power to 16 series-connected photodiodes. The PH18 MA Tower Semiconductor PDK photodiode is implemented in a germanium on silicon vertical P-I-N configuration, where a germanium layer is formed on top of the Si strip waveguide to absorb the light. The photodiode has a width of 8.6 μm and a length of 15 μm. To connect the 0.5 μm width MMI network waveguides to the 8.6 μm width photodiode waveguides, linear tapers are used.

The microring modulator is implemented in longitudinal rate-race layout with charge depletion modulator on both sides (FIG. 23A). One of the main design goals of the modulator is to increase the modulation efficiency, i.e., the percentage of the modulator length with respect to the total round-trip length of the ring modulator. This ensures the maximum possible wavelength shift tuning for the same applied modulating voltage value. The microring resonator coupling length and the waveguide bends radius should then be minimized. Also, the total loss of the ring modulator should be minimized to achieve high quality factor (Q) and small full-width half-maximum (FWHM) that lead to better switching extension ratio. For the same reason, the microring modulator is designed to work under critical coupling condition. The microring resonators have a narrow strip waveguide width of 0.4 μm (less optical field confinement, hence strong coupling) so that the targeted critical resonance coupling coefficient can be obtained with a smaller coupling length (20 μm in their design). Euler 90° veguide bends with 5 μm radius are used to minimize the un-modulated length without introducing high loss to the ring; the simulated loss is 0.02 dB. The standard technology lateral P-I-N built into ridge waveguide charge depletion phase modulator was used to implement the modulated section of the ring resonator. The ridge waveguide used to implement the charge depletion modulator has a strip width of 0.45 μm, and total modulation length of L_{mod}. Ridge to strip waveguide tapers with length of 10 μm are used to connect the two modulator sections inside the ring resonator. Charge depletion modulator is suitable to be driven with the photovoltaic mode photodiodes as it does not drain any current. The loss of the phase modulator is 2.5 dB/mm and the modulation efficiency V_{π}L_{π} is 1.8 V·cm. High modulator efficiency is needed to induce more resonance shift. Three different version of the logic gate with three different L_{mod} of 250 μm, 500 μm, and 1000 μm were fabricated. The unmodulated length that includes the coupling region, the bends, and the ridge to strip tapers is 110 μm. This makes the ring modulation efficiency equal to 70%, 82%, and 90% for the ring with the modulation lengths of 250 μm, 500 μm, and 1000 μm, respectively. A micrograph of the fabricated optical-optical logic gate with ring modulator length of 250 μm is shown in FIG. 23B. The active area of the optical logic gate is around 0.1 mm2.

In this section, the experimentally-demonstrated operations of the optical logic gate are discussed. First, the measurement results of the optical to voltage converter and the static response of the optical-optical logic gate are shown. Then, the dynamic responses for different logic operations of the logic gate are shown. Lastly, the dynamic speed limit of the proposed logic gate is presented. The measurement setup relies on external intensity modulator to modulate the optical carrier with electrical data, and polarization controllers to optimize the coupling efficiency to the chip through the grating couplers. The temperature mismatch between the two off-chip input paths creates a time-varying phase offset between the two input signals when generated from the same source (coherent case). Therefore, the reported experiments correspond to the incoherent input signals.

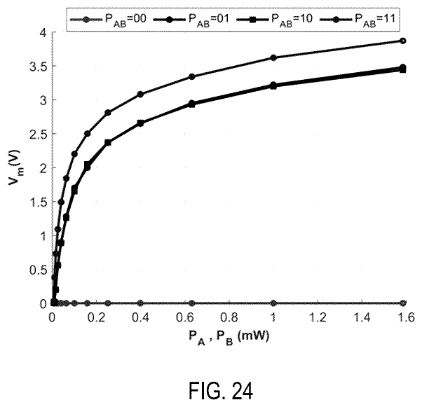

Static response: to test the zero-bias optical power to voltage converter, a standalone test structure with the combiner and the optical power to voltage converter was used (refer to FIG. 23A). FIG. 24 shows the measured output voltage Vₘ versus the optical input CW power levels (P_{A} and P_{B}). This measurement was conducted for different input logic configurations: P_{A}B=11 when both P_{A} and P_{B} are ON and are swept simultaneously, P_{AB}=01 when P_{A}=O and P_{B} is ON and swept, P_{AB}=10 when P_{B}=O and P_{A} is ON and swept, and P_{AB}=00 when both P_{A}=O and P_{B}=0 (Vₘ is 0 in this case). In case of P_{AB}=01/10 the input power to the optical power to voltage converter Pm is half P_{A} or P_{B} and it is equal to P_{A} or P_{B} when P_{AB}=11, as discussed in combiner operation in the concept section. As expected, the optical power to voltage transfer function is nonlinear, the output voltage starts to saturate as it reaches the diode open circuit voltages. At any given input optical power larger than 0.1 mW, the measured output voltage (Vₘ) for the case of input logic 10/01 and 11 are very close to each other, around 0.4 V difference. This makes the corresponding resonance wavelengths close to each other as discussed earlier.

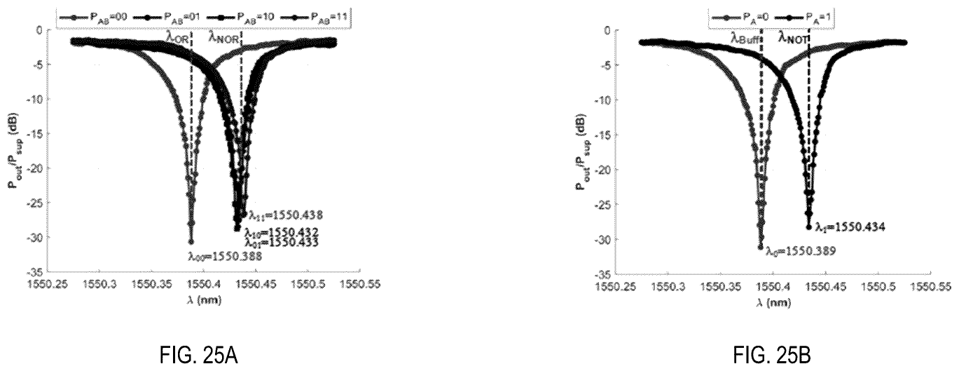

The logic gate wavelength transmission resonance wavelengths for two operand (A and B) and one operand (A) cases are shown in FIG. 25A and FIG. 25B, respectively, where the logic high optical power P_{H} is 0.1 mW and P_{L} is 0 mW. For the two operands case, the separation (Δλᵣ₁) between the resonance wavelengths corresponding to input logic level “00” (λ₀₀) and “01/10” (λ₀₁/λ₁₀) is much larger than the shift (Δλᵣ₂) between the resonance wavelengths corresponding to the input logic levels “01/10” (λ₀₁/λ₁₀) and “11” (λ₁₁). As explained before, to realize the OR gate function, the unmodulated resonant wavelength of the microring modulator (“00” resonant wavelength) is set to be equal to the “supply” wavelength. To realize the NOR gate function, the modulated resonant wavelength of the microring modulator corresponding to “01/10” and “11” input logic levels is set to be equal to the “supply” wavelength. For one operand operation, the two-resonance wavelength corresponding to input logic levels “0” (λ₀) and “1” (λ₀) are clearly separated (Δλᵣ₁), Buffer and NOT operations can be obtained at these wavelengths, respectively.

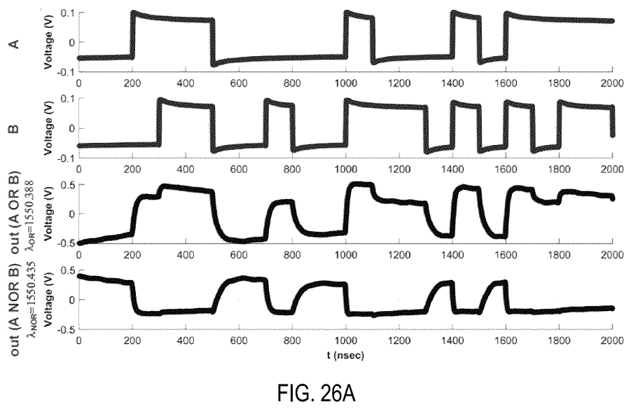

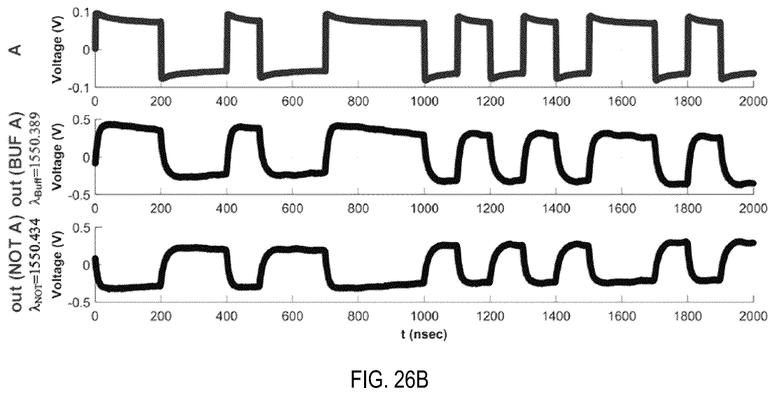

Dynamic response: to test the dynamic performance of the all-optical logic gate, 10 Mbps PRBS OOK data is used. An arbitrary waveform generator was used to generate PRBS. External modulators were used to generate the optical data to the logic gate (P_{A} and P_{B}). The power level of the two logic inputs (P_{A} and P_{B}) in the two-operand case are matched by observing the optical power levels of the monitor signal Pₘₒₙᵢₜₒᵣ which is a small replica of signal after the optical combiner Pm. When P_{A}=P_{B}, the monitor signal should have three power levels: low power level for “00” input, mid power level for “01” and “10” inputs, and high power level for “11” input. The input, the monitor and the output data are detected using an oscilloscope. The ring modulator input Pₛᵤₚ carrier wavelength is matched to the resonance wavelength of the desired operation as mentioned in the static measurements section and shown FIG. 25A and FIG. 25B. The dynamic measurement results for two operands case showing the logic operations of OR and NOR are shown in FIG. 26A. The logic operations of Buffer and NOT for the one operand case are shown in FIG. 26B. In the case of OR gate, there are slightly two different high or “1” output levels corresponding to “01/10” or “11” input cases. In this case, the ring resonance wavelength is matched to the supply wavelength when both input levels are low or “00” (red curve in FIG. 25A). The resonance wavelength shifts by slightly different amounts in the case of “01/10” and “11” input levels as shown in Black and Blue curves in FIG. 25B. This results in slightly different transmission levels in the cases of “01/10” and “11” input levels. On the other hand, the NOR operation works at the intersection wavelength of the input logic resonances “01/10” and “11” for the “0” output (resonances in Blue and Black curves of FIG. 5A); hence, it has only one “0” level. NOR is a universal logic gate that can be used to implement any logic function. The output detected voltage for the case of the NOT and the NOR operation is lower than the cases of Buffer and OR as the ring modulator has lower extension ratio at these wavelengths, as shown in FIG. 25. The extinction ratio decreases when either P_{A} or P_{B} are high as the quality factor of the ring modulator is decreased when more carriers are induced in the ring.

Speed measurements: there are two factors that limit the switching speed of the proposed architecture: (1) the microring modulator build up and decay times, and (2) the electrical resistance and capacitance time constant at the microring modulator's voltage modulating node. The optical delay can be determined by the photon lifetime in the microring cavity which defined as τₚₕ=λQ/2πc. The smallest ring modulator (L_{mod}=250 μm) has the largest Q and hence the largest optical delay τₚₕ=18 ps. The electron RC time constant is τₑₗ=R_{PD}(C_{PD}+C_{mod}), where R_{PD} and C_{PD} are the photovoltaic photodiode internal resistance and capacitance, respectively, and C_{mod} is the ring modulator (reverse-biased PN depletion) capacitance. This value depends on the applied reverse voltage of the charge depletion modulator as C_{mod} is inversely proportional to the reverse voltage. In case of the photovoltaic mode operation of the photodiode (due to its large R_{PD} and C_{PD}), el is in the range of 10 s-100 s of ns and it dominates the total delay (limiting the data-rate) of the system expressed as τ=τₚₕ+τₑₗ. The −3 dB bandwidth (BW_{-3 dB}) of the logic gate can be defined as BW_{-3 dB}=1/(2ππ)=2.2/(2πt_{rf}), where t_{rf} is the average 10%-90% rise (t_{f}) and fall time (t_{f}) of the system (t_{rf}=0.5(tᵣ+t_{f})). The maximum operated data rate (DR) is directly proportional to the BW?3 dB and can be defined as DR=2.9BW_{-3 dB} for the NRZ data.

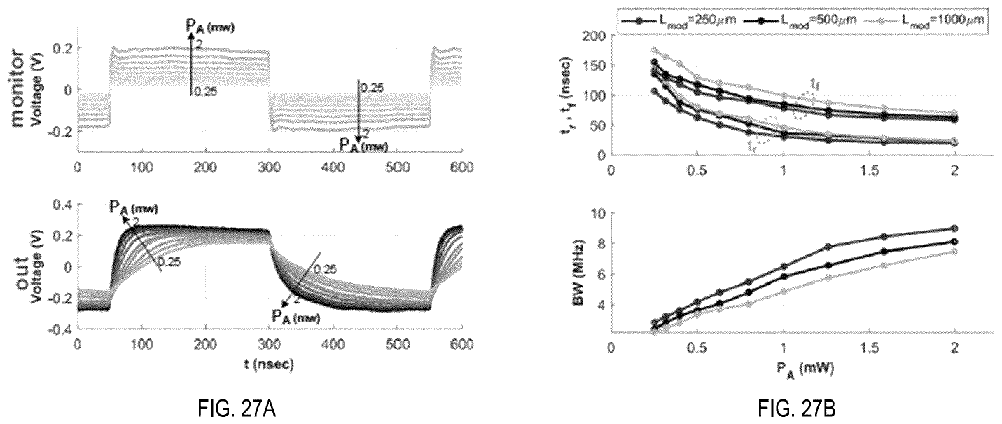

To measure the BW, 3 dB of the optical logic gate, a 2 MHz square-wave signal pulse train is applied as the input A, while the gate operates in the Buffer mode, and tᵣ and t_{f} of the output data Pout are observed. This test was conducted for all the ring designs (L_{mod}=250 μm, 500 μm, and 1000 μm). Different optical square-wave amplitude powers are used to capture the dependence of the C_{mod} on the applied modulating voltage Vₘ (FIG. 27A). As the PA switching power increases, the switching modulating voltage Vₘ increases, and hence the C_{mod} reduces and the BW_{3 dB} increases, as shown in FIG. 27B. In case of the buffer operation, tᵣ is smaller than t_{f} due to the voltage dependency of C_{mod}, as the final voltage in case of the rising edge is larger than the case of the falling edge and hence the equivalent C_{mod} is smaller in the case of the rising edge. Also, it can be noticed the smallest microring design (L_{mod}=250 μm) has the higher BW_{-3 dB} as it has the smallest C_{mod}; the other part of the node capacitance C_{PD} does not depend on L_{mod}.

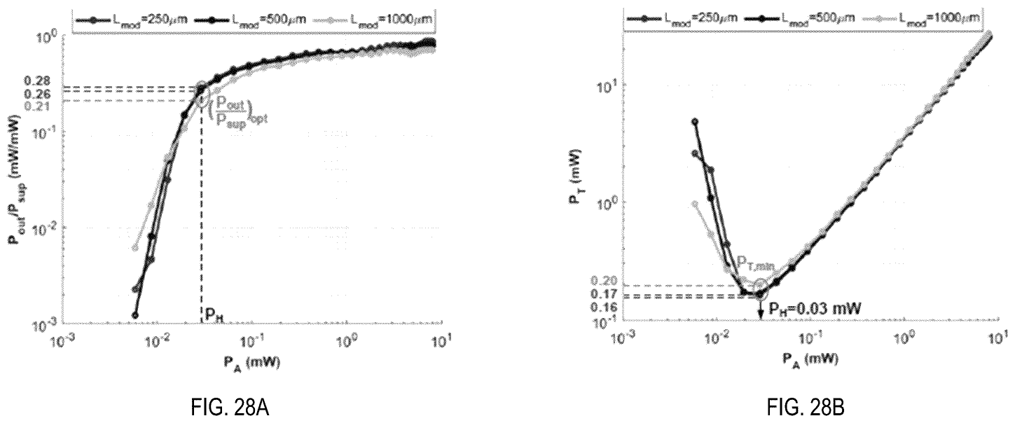

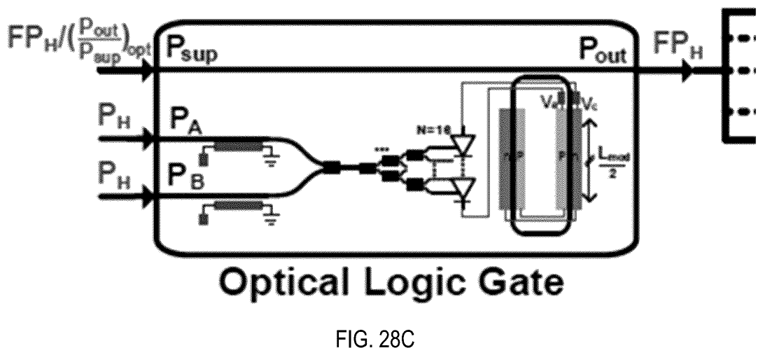

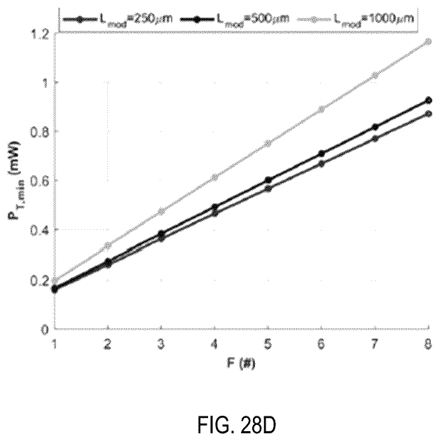

In some embodiments, an optical digital circuit includes several universal optical logic gates. Each optical gate can drive one or more subsequent optical logic gates. The output optical power level of each logic gate should be sufficient to drive the subsequent logic gates. The output power level of their universal optical logic gate depends on the optical power levels of the logic input operands (P_{A} and P_{B}) and the optical power level of the “supply bus”, Pₛᵤₚ, that feeds the ring modulator. FIG. 28A shows the ring modulator transmission Pₒᵤₜ/Pₛᵤₚ versus the input logic power level (P_{A}) in the single-operand case for three different ring modulator designs having L_{mod} of 250 μm, 500 μm, and 1000 μm. The L_{mod} does not affect the results significantly, as the increase in resonance shift for modulators with larger L_{mod} is offset by the decrease of corresponding Q. Overall, the smallest ring modulator achieves a little more efficient switching. To ensure straightforward cascading of such optical gates, the input and output logic levels should be the same. The total optical power consumed in one such optical logic gate is

$${P}_{T} = {P}_{A} + {P}_{B} + {P}_{sup} = 2 {P}_{A} + \frac{{P}_{out}}{( \frac{{P}_{out}}{{P}_{sup}} )} = 2 {P}_{A} + {P}_{A} / ( {P}_{out} / {P}_{sup} ) ,$$

where they used the fact that in a proper logic gate, input and output logic levels should be the same (all equal to P_{A}). FIG. 28B shows the total required optical power, P_{T}, versus logic high optical level, P_{A}, using the measured Pₒᵤₜ/Pₛᵤₚ data shown in FIG. 28A. The logic high optical power level that can switch the optical gate at the smallest overall optical power required by the gate is found to be P_{H}=30 W. The corresponding optimum Pₒᵤₜ/Pₛᵤₚ values (Pₒᵤₜ/Pₛᵤₚ)ₒₚₜ are 0.28, 0.26, and 0.21 and P_{T,min} values are 160 μW, 170 μW, and 200 μW for L_{mod} of 250 μm, 500 μm, and 1000 μm, respectively. In summary, the optical logic gate built using Lmod=250 μm can require a total optical power P_{T}=160 μW to operate. In some examples, the optical logic gate may have more power to drive multiple similar optical logic gates. The total power for an optical gate driving F similar gates (fanout of F as shown in FIG. 28C) is equal to P_{T}=2P_{A}+F·Pₒᵤₜ/(Pₒᵤₜ/Pₛᵤₚ). The minimum total energy consumption of such a gate can be given by P_{T,min}=2P_{H}+F·P_{H}/(Pₒᵤₜ/Pₛᵤₚ)ₒₚₜ. In some embodiments, as shown in FIG. 28C, the optical circuits disclosed herein can include a plurality of stacked photodiodes. For example, the combiner of the optical circuit can be operatively coupled with or include a plurality of stacked photodiodes configured to receive a first optical input signal and a second optical input signal, and convert into one or more electrical signals. FIG. 28D shows the P_{T,min} for different fanout value for the three L_{mod} values. In a complex digital logic circuit, the input optical power should be considered only in the input stages because the input power levels of the subsequent stages are provided by the supply powers of preceding stages.

An example integrated zero-bias universal optical logic gate is demonstrated. The logic gate combines the power level of the optical operands, then converts it to electrical voltage using photodiodes operating in the photovoltaic mode resulting in resonance wavelength shift of a microring resonator depending on the combined power level. Different logic operations including OR, NOR, XOR, XNOR, and NAND may be realized. More complex all-optical logic circuits using the proposed universal all-optical logic gates may be created without requiring any electrical voltages. The operation speed of the optical logic gates can be extended to Gbps range by operating the photodiodes in the photoconductive mode (using a DC supply voltage) instead of the photovoltaic mode (zero-bias operation).

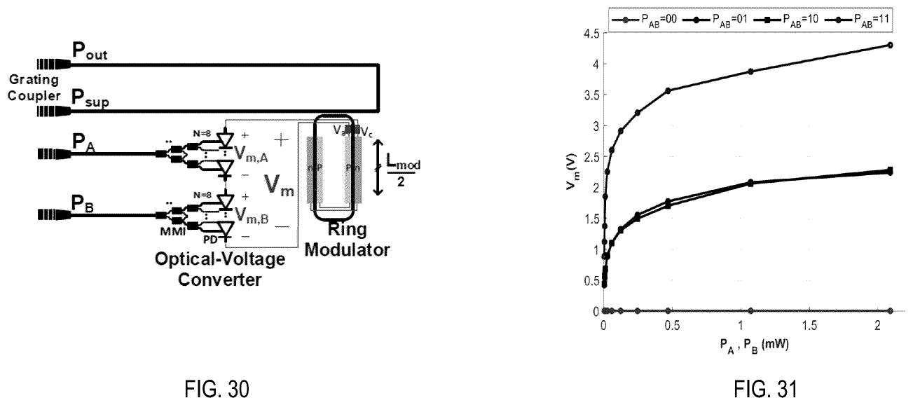

In some embodiments, the example optical logic gates discussed above can include a signal combiner whose output controls the resonant wavelength of a microring resonator. In the implemented optical logic gates, signal combining occurs in the optical domain. As an alternative approach to optical power combining, the two optical input signals can be converted to electric voltages through photovoltaic photodiodes that are connected in series (FIG. 29A). The overall voltage across the series-connected photodiodes is hence the addition of individual voltages across each photodiode. Signal combining in electrical domain is insensitive to the wavelengths or coherency of the two optical inputs. Unlike the case of optical power combining, the resonant wavelength shift of the microring modulator is a linear function of the input power levels (FIG. 29B). This is because, irrespective of the nonlinear characteristic of each photovoltaic photodiode converting P_{H} to V_{PD}, the combined voltage that is applied to the microring modulator is always a linear function of the total input power. The modulating voltage can be 0, V_{PD}, and 2V_{PD} when both input power levels are zero (00 logic input), only input power level is P_{H} (01 and 10 input logics), and both input power levels are P_{H} (11 input logic), respectively. This feature can be used to realize other gate functions. For instance, consider the case where the unmodulated resonant wavelength of the microring modulator is far enough from the wavelength of the “supply” source in a way that modulating voltage 2V_{PD} is needed to shift the resonant wavelength of the microring modulator to match the wavelength of the supply source. Modulating voltage V_{PD} does not provide sufficient wavelength shift to match the “supply” wavelength. This gate can then emulate a NAND function (FIG. 29E). FIG. 30 shows the complete schematic of a zero-biased silicon photonics logic gate where the two input signals are combined in the electrical domain. The optical to voltage converter section can be fabricated as a standalone test structure. As shown, in some embodiments, the combiner of the optical circuits disclosed herein can be operatively coupled with or include a plurality of first stacked photodiodes and a plurality of second stacked photodiodes. The first stacked photodiodes can be configured to receive the first optical input signal and convert into one or more first electrical signals, and the second stacked photodiodes can be configured to receive the second optical input signal and convert into one or more second electrical signals. The measured output voltage Vₘ versus the optical input CW power levels (P_{A} and P_{B}) is shown in FIG. 31. As expected, the generated voltage in case of “11” logic input is as twice the case of “01/10”.

Described and shown above are non-limiting example embodiments and/or non-limiting example demonstration (e.g., fabrication, measurement, etc.) of the optical circuits disclosed herein. Various other embodiments are described in greater detail in “Universal all-optical zero-bias logic gates in silicon photonics” (Optics Express 36063, Vol. 32, No. 21, Oct. 7, 2024) and Chapter 4 of “Silicon photonics integrated circuits for analog and digital optical signal processing” (University of Southern California, Thesis by Samer Sayed Bahr Idres, May 2024), which are incorporated herein by reference in its entirety.

As utilized herein the terms “circuit” and “circuitry” refer to physical electronic components (e.g., hardware) and any software and/or firmware (“code”) which can configure the hardware, be executed by the hardware, and/or otherwise be associated with the hardware. As utilized herein, “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}. As utilized herein, the term “exemplary” means serving as a non-limiting example, instance, or illustration. As utilized herein, the terms “e.g.” and “for example” set off lists of one or more non-limiting examples, instances, or illustrations.

The components, steps, features, objects, benefits and advantages which have been discussed are merely illustrative. None of them, nor the discussions relating to them, are intended to limit the scope of protection in any way. Numerous other embodiments are also contemplated. These include embodiments which have fewer, additional, and/or different components, steps, features, objects, benefits and advantages. These also include embodiments in which the components and/or steps are arranged and/or ordered differently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

All articles, patents, patent applications, and other publications that have been cited in this disclosure are incorporated herein by reference.

The phrase “means for” when used in a claim is intended to and should be interpreted to embrace the corresponding structures and materials that have been described and their equivalents. Similarly, the phrase “step for” when used in a claim is intended to and should be interpreted to embrace the corresponding acts that have been described and their equivalents. The absence of these phrases from a claim means that the claim is not intended to and should not be interpreted to be limited to these corresponding structures, materials, or acts, or to their equivalents.

Relational terms such as “first” and “second” and the like can be used solely to distinguish one entity or action from another, without necessarily requiring or implying any actual relationship or order between them. The terms “comprises,” “comprising,” and any other variation thereof when used in connection with a list of elements in the specification or claims are intended to indicate that the list is not exclusive and that other elements can be included. Similarly, an element preceded by an “a” or an “an” does not, without further constraints, preclude the existence of additional elements of the identical type.

What is claimed is:

1. An optical circuit comprising:
an optical waveguide configured to receive a continuous wave optical signal and emit an output signal;
an optical combiner configured to receive first and second optical signals and combine the first and second optical signals to produce a combined optical signal;
a photodetector configured to receive the combined optical signal and convert the combined optical signal into an electrical voltage signal; and
a resonator coupled to the optical waveguide and configured to receive the continuous wave optical signal and/or the electrical voltage signal,
wherein the optical waveguide is configured to emit the output signal based on the electrical voltage signal applied on the resonator.

2. The optical circuit of claim 1, wherein the first and second optical signals have substantially the same wavelength and/or substantially the same phase.

3. The optical circuit of claim 1, wherein:
(i) the first and second optical signals have a first optical power corresponding to a logic-high state;
(ii) the first and second optical signals have a second optical power corresponding to a logic-low state; or
(iii) the first optical signal has the first optical power, and the second optical signal has the second optical power.

4. The optical circuit of claim 1, wherein the resonator is a tunable microring resonator.

5. The optical circuit of claim 1, wherein the output signal is dependent on a location of a resonant wavelength relative to a wavelength of the continuous wave optical signal.

6. An optical logic circuit comprising:
an optical waveguide having a continuous wave optical signal coupled to an input of the optical waveguide;
a first optical signal input waveguide having a first optical input signal;
a second optical input signal waveguide having a second optical input signal;
a combiner coupled to the first and second optical input signal waveguides to receive the first and second optical input signals and combine the first and second optical input signals into a combined input signal;
an optical resonator coupled to the optical waveguide and configured to receive the combined input signal, wherein:
the optical resonator is configured to change a resonant wavelength of the optical resonator based on an amplitude of the combined input signal; and
the optical waveguide is configured to output an output signal at an output of the optical waveguide, the output signal having an amplitude varying based on the resonant wavelength of the optical resonator.

7. The optical logic circuit of claim 6, wherein the optical resonator comprises a microring resonator having a semiconductor junction biased by an electrical voltage corresponding to the amplitude of the combined input signal.

8. The optical logic circuit of claim 6,
wherein the combiner includes a first photodiode coupled to the first optical signal input waveguide and a second photodiode coupled to the second optical signal input waveguide,
wherein the combiner is configured to provide a first electrical signal and a second electrical signal based on the first optical input signal and the second optical input signal, respectively, and
wherein the combined input signal includes the first electrical signal and the second electrical signal.

9. The optical logic circuit of claim 8, further comprising a power source coupled to the first photodiode and the second photodiode, the power source configured to provide a modulating voltage, wherein the optical resonator is configured to receive the first electrical signal, the second electrical signal, and the modulating voltage.

10. The optical logic circuit of claim 6, wherein the combiner includes a plurality of stacked photodiodes configured to receive the first optical input signal and the second optical input signal, and convert into one or more electrical signals.

11. The optical logic circuit of claim 6, wherein the combiner includes a plurality of first stacked photodiodes configured to receive the first optical input signal and convert into one or more first electrical signals, and a plurality of second stacked photodiodes configured to receive the second optical input signal and convert into one or more second electrical signals.

12. A universal optical logic circuit comprising:
a microring resonator comprising a plurality of inputs;
a plurality of optical signal input waveguides coupled to the plurality of inputs of the microring resonator and configured to provide (i) a first logic input optical signal and (ii) a second logic input optical signal; and
an optical waveguide coupled to the microring resonator and including an input configured to receive a continuous wave optical signal having a first input amplitude and an output configured to emit an output signal,
wherein the output is configured to emit the output signal having a logic state determined based on a first logical operation of the microring resonator on the first logic input optical signal and the second logic input optical signal.

13. The universal optical logic circuit of claim 12, wherein the output optical signal comprises the continuous wave optical signal having a first output amplitude, and the first output amplitude depends on the logic state.

14. The universal optical logic circuit of claim 13, further comprising a temperature controller configured to increase or decrease a temperature of the microring resonator to maintain the microring resonator at an approximately constant temperature.

15. The universal optical logic circuit of claim 12,
wherein:
the output optical signal has three states associated with a logic-high amplitude, a logic-low amplitude, and a logic-intermediate amplitude of the continuous wave optical signal, respectively; and
each of the logic-high amplitude, the logic-low amplitude, and the logic-intermediate amplitude is less than or equal to the first input amplitude, or
wherein:
the output optical signal has two states associated with a logic-high amplitude and a logic-low amplitude of the continuous wave optical signal, respectively; and
each of the logic-high amplitude and the logic-low amplitude is less than or equal to the first input amplitude.

16. The universal optical logic circuit of claim 11, wherein the universal optical logic circuit is connected to another universal optical logic gate or circuit configured to perform at least one of (i) a logic operation to provide a one-bit digital full adder and (ii) an operation to provide a pattern detector.

17. The universal optical logic circuit of claim 11, wherein the first logical operation comprises at least one of a NAND operation, an OR operation, and an XNOR operation.

18. The universal optical logic circuit of claim 11, wherein a resonant wavelength of the microring resonator is tuned by at least a first optical power of the first logic input optical signal and a second optical power of the second logic input optical signal.

19. The universal optical logic circuit of claim 11, further comprising:
a coupler to extract a fraction of optical power from the first logical input optical signal and the second logical input optical signal; and
a photodetector connected to the coupler to generate an electrical voltage having a magnitude proportional to the fraction of the optical power,
wherein the microring resonator comprises a semiconductor junction having the electrical voltage applied across the semiconductor junction to bias the semiconductor junction.

20. The universal optical logic circuit of claim 19, wherein the semiconductor junction is a P-N junction or a PIN junction.
